(19) United States
(12) Patent Application Publication
(10) Pub. No.: US 2025/0176434 A1
(43) Pub. Date: May 29, 2025

(54) PIEZOELECTRIC TRANSDUCER HAVING TAPERED CANTILEVER

(71) Applicant: TEXAS INSTRUMENTS INCORPORATED, Dallas, TX (US)

(72) Inventors: Udit Rawat, Allen, TX (US); Bichoy Bahr, Allen, TX (US); Kashyap Mohan, Irving, TX (US); Baher Haroun, Allen, TX (US)

(21) Appl. No.: 18/522,145

(22) Filed: Nov. 28, 2023

(51) Int. Cl. H10N 30/30; H10N 30/082; H10N 30/20; H10N 30/80; H10N 30/87

(52) U.S. Cl. CPC H10N 30/306; H10N 30/082; H10N 30/2044; H10N 30/802; H10N 30/875

(57) ABSTRACT

A transducer device is described which comprises a substrate having an opening through the substrate. The transducer device further comprises a first tapered cantilever having a first edge and a second edge, wherein the first edge is opposite to the second edge, wherein the first edge is on the substrate, wherein at least part of the second edge is suspended over the opening, the second edge being longer than the first edge. The transducer device further comprises a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

### BACKGROUND

A transducer can convert between mechanical energy (e.g., vibration) and electrical energy. A speaker of an audio device is one such example of a transducer and may include a membrane that can vibrate to generate audible sound waves or acoustic signal in response to an audio signal. An audio device, such as a microphone, can also include a cantilever flap (e.g., a piezoelectric flap) with one end fixed and the other end suspended over an empty space. The piezoelectric flap can vibrate in response to external sound waves and generate electrical signals representing the sound waves. The electrical signals can then be further processed, for example, to generate an audio signal or to extract other information. A piezoelectric flap may be a piezoelectric bimorph flap having a relatively large area. For a microphone, a large flap area allows the microphone to detect small sound pressure, which can improve sensitivity. For a speaker, a large flap area allows the speaker to generate vibration with more power, which can improve efficiency. However, increasing the area of the piezoelectric flap can increase the footprint of the audio device, lower the resonance frequency to where it can cause interference, and degrade the structural integrity of the cantilever.

### BRIEF DESCRIPTION OF DRAWINGS

The examples will be understood more fully from the detailed description given below and from the accompanying drawings, which, however, should not be taken to limit the disclosure to the specific examples, but are for explanation and understanding only.

FIG. 1 is a schematic illustrating an audio system with tapered cantilevers for a microphone, in accordance with at least one example.

FIG. 2 is a schematic illustrating a top view of a microphone with tapered cantilevers, in accordance with at least one example.

FIG. 3A is a schematic illustrating a top view of a flap of a tapered cantilever, in accordance with at least one example.

FIG. 3B is a schematic illustrating a cross-sectional view of the flap of the tapered cantilever, in accordance with at least one example.

FIG. 4A is a schematic illustrating a three-dimensional (3D) view of a microphone with tapered cantilevers, in accordance with at least one example.

FIG. 4B is a schematic illustrating a zoomed view showing two adjacent flaps of the tapered cantilevers, in accordance with at least one example.

FIG. 5 is a schematic illustrating a cross-section of an audio device including the audio system having the tapered cantilevers, in accordance with at least one example.

FIG. 6 is a schematic illustrating a processing circuit coupled to tapered cantilevers that are anchored to a post, in accordance with at least one example.

FIGS. 7A, 7B, 7C, 7D, 7E, 7F, 7G, and 7H are schematics illustrating cross-sections of piezoelectric bimorph cantilevers, according to some examples.

FIG. 8A is a schematic illustrating stress along the direction of length of a tapered cantilever structure, in accordance with at least one example.

FIG. 8B is a plot illustrating stress as a function of time for tapered and non-tapered cantilevers, in accordance with at least one example.

FIG. 9A is a schematic illustrating a top view of a microphone with tapered cantilever, in accordance with at least one example.

FIG. 9B is a schematic illustrating beam displacement near an outer edge of the tapered cantilever, in accordance with at least one example.

FIG. 9C is a plot illustrating sensitivity as a function of frequency of a microphone with tapered cantilevers, in accordance with at least one example.

FIG. 10A is a schematic illustrating a top view of a microphone with tapered cantilevers surrounded by a dam, in accordance with at least one example.

FIG. 10B is a schematic illustrating a structure for stress and misalignment control near the outer edge of the tapered cantilever and the dam, according to at least one example.

FIG. 11 is a schematic illustrating a structure for stress and misalignment control near the outer edge of the tapered cantilever and the dam, according to at least one example.

FIGS. 12A, 12B, 12C, 12D, 12E, 12F, 12G, and 12H are schematics illustrating the process of fabricating a microphone with tapered cantilevers, in accordance with some examples.

FIGS. 13A, 13B, and 13C illustrate methods of forming a microphone with tapered cantilevers anchored to a post, in accordance with some examples.

FIG. 14 and FIG. 15 are schematics illustrating example systems including a transducer device with tapered cantilevers, in accordance with some examples.

### SUMMARY

In at least one example, a transducer device is provided which comprises a substrate having an opening through the substrate. The transducer device further comprises a first tapered cantilever having a first edge and a second edge, wherein the first edge is opposite to the second edge, wherein the first edge is on the substrate, wherein at least part of the second edge is suspended over the opening, the second edge being longer than the first edge. In at least one example, the transducer device further comprises a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

In at least one example, a system is provided which comprises a case, an integrated circuit, and a transducer device coupled to the integrated circuit. The integrated circuit and the transducer device are covered by the case, wherein the transducer device includes a substrate having an opening through the substrate. In at least one example, the transducer device includes a first tapered cantilever having a first edge and a second edge, wherein the first edge is opposite to the second edge. The first edge is on the substrate, and at least part of the second edge is suspended over the opening, the second edge being longer than the first edge. The first tapered cantilever including first electrodes is electrically coupled to the integrated circuit. In at least one example, the transducer device further comprises a second tapered cantilever having a third edge and a fourth edge, wherein the third edge is opposite to the fourth edge. The third edge is on the substrate, and at least part of the fourth edge is suspended over the opening, the fourth edge being longer than the third edge. The second tapered cantilever including second electrodes is electrically coupled to the integrated circuit.

In at least one example, a method for fabricating a transducer device is described where the method comprises forming a substrate having an opening through the substrate. The method further comprises forming a first tapered cantilever having a first edge and a second edge, wherein the first edge is opposite to the second edge. The first edge is on the substrate, and at least part of the second edge is suspended over the opening, the second edge being longer than the first edge. The method further comprises forming a second tapered cantilever having a third edge and a fourth edge, wherein the third edge is opposite to the fourth edge. The third edge is on the substrate, and at least part of the fourth edge is suspended over the opening, the fourth edge being longer than the third edge.

In at least one example, a transducer device is provided which comprises a structure and a first tapered cantilever having a first edge attached to the structure and a second edge away from the first edge, wherein the second edge is longer than the first edge. The transducer device further comprises a second tapered cantilever having a third edge attached to the structure and a fourth edge away from the third edge, wherein the third edge is longer than the second edge.

In at least one example, a transducer device is provided which comprises a post and a plurality of tapered cantilevers having a first edge attached to the post and a second edge away from the first edge, wherein the plurality of tapered cantilevers is positioned around the post.

In at least one example, a system is provided which comprises a case, an integrated circuit, and a transducer device coupled to the integrated circuit. The integrated circuit and the transducer device are covered by the case, wherein the transducer device includes: a post; and a plurality of tapered cantilevers having a first edge attached to the post and a second edge away from the first edge, and wherein the plurality of tapered cantilevers is positioned around the post.

### DETAILED DESCRIPTION

As described above, an audio device, such as a microphone or a speaker, may include a piezoelectric cantilever in the form of a flap to convert between electrical energy and mechanical energy. To increase the sensitivity of the microphone in detecting sound waves, or to increase efficiency of the speaker in generating sound waves, the piezoelectric flap may have a relatively large area. However, increasing the area of the piezoelectric flap can increase the footprint of the audio device and lower the resonance frequency of the device. Also, the weight of the large piezoelectric flap suspended over an empty space can also degrade the overall structural integrity of the cantilever, making the suspended portion of the flap prone to break off. A piezoelectric bimorph flap with smaller area can be achieved with smaller structure dimensions, but such reduction in structure dimensions result in a reduction in stiffness of the piezoelectric bimorph flap leading to degradation of the overall signal-to-noise ratio (SNR).

Disclosed herein is a transducer device with a plurality of tapered cantilevers coupled to (and anchored to) a post at a center. The post may be a silicon post and part of a substrate and provides mechanical stability to a die having the audio device. In at least one example, a tapered cantilever has two opposite edges with different dimensions, where a first edge with shorter dimension or length is attached to the post while a second edge with longer dimension and opposite to the first edge is not attached to any substrate. In at least one example, the plurality of tapered cantilevers is arrayed in a polygonal configuration with shorter edges of the plurality of tapered cantilevers attached to the post. Any number of tapered cantilevers may be arrayed in the polygonal configuration. For example, the polygonal configuration may be an octagonal configuration with tapered cantilevers around the post. In at least one example, the tapered cantilevers are in a symmetrical configuration in relation to the post. In at least one example, the area reserved for one cantilever in the polygonal configuration is used for routing one or more interconnects to the post. In at least one example, one or more interconnects or wires are routed to the post through a substrate from under the plurality of tapered cantilevers. In at least one example, one or more interconnects or wires are routed to the post over the plurality of tapered cantilevers.

In at least one example, a processing circuit or integrated circuit is coupled to the transducer device and configures/operates the transducer device to provide a particular function, such as a microphone (e.g., audio sensor), a speaker, a stress sensor, an accelerometer, an energy harvester, etc. The processing circuit can also apply a voltage to one or more electrodes of the plurality of tapered cantilevers to set their initial state. The cantilevers may have residual stress that cause the cantilevers to bend in the post-release state. The application of a voltage across the cantilever can flatten it, or otherwise set the initial state (e.g., prior to receiving an external force/pressure) of the cantilever, which can reduce the air gap between the movable long edge and the fixed substrate edge of the cantilever, for example.

The example transducer devices can be part of any device that relies on piezoelectric effect to perform conversion between electrical energy and mechanical energy, such as an audio device (e.g., a microphone, a speaker, etc.), a stress sensor, an accelerometer, etc.

The examples discussed herein can provide various advantages. For instance, stress enhancement or amplification is achieved by anchoring shorter edges of the tapered cantilevers to the post in the center of the tapered cantilevers. Stress enhancement or amplification improves the electromechanical coupling and the efficiency of transduction (conversion between mechanical and electrical energies). In a case where the tapered cantilevers are part of a sensing device (e.g., a microphone, an accelerometer, etc.), the improved efficiency of transduction can improve the signal-to-noise ratio (SNR) and sensitivity. In a case where the tapered cantilevers are part of an actuator (e.g., a speaker), the improved efficiency of transduction allows generation of a larger degree of movement for a particular electrical potential/voltage, and improves the efficiency of actuation.

Tapered cantilevers can also improve the overall structural integrity of the transducer. Specifically, the central post can provide additional mechanical rigidity to the structure comprising the plurality of cantilevers and thus makes handling of dies with such structures easier to handle during fabrication. By anchoring or clamping the shorter edges of the plurality of tapered cantilevers to the post, the area of the transducer device can be reduced as shorter or smaller tapered flaps can be used because of stress amplification, which can reduce the footprint of the transducer device. Also, the tapered flaps can have smaller weights, which can improve the overall structural integrity of the cantilever as the flaps are less prone to break off due to the mechanical stress caused by their weights. Other technical effects will be evident from various examples described herein. Here, the same reference numbers or other reference designators are used in the drawings to designate the same or similar (either by function and/or structure) features.

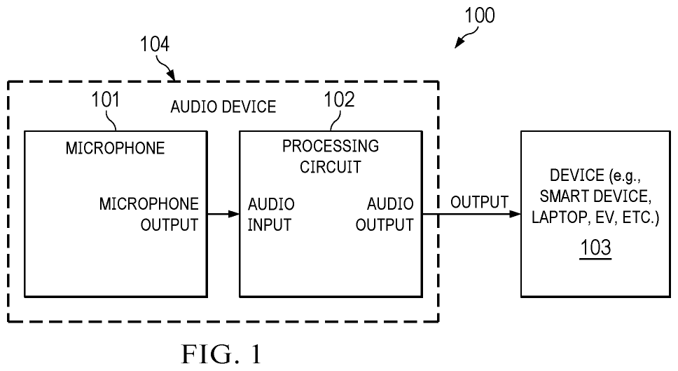

FIG. 1 is a schematic illustrating a system 100 with tapered cantilevers for a microphone, according to at least one example. System 100 may comprise a microphone 101, a processing circuit 102, and a device 103. Microphone 101 and processing circuit 102 can be part of an audio system 104. In at least one example, microphone 101 comprises a micro-electromechanical system (MEMS) or a nano-electromechanical system (NEMS) that converts mechanical energy from incident sound waves. Microphone 101 can output an analog electrical signal on a microphone output to an audio input of processing circuit 102.

In at least one example, microphone 101 comprises a plurality of tapered cantilever flaps that includes electrodes. In at least one example, the plurality of tapered cantilever flaps is a set of biomorph cantilever flaps with shorter edges attached to a central post. The plurality of tapered cantilever flaps can vibrate responsive to external sound waves and generates electrical signals representing the sound waves. The output from the plurality of tapered cantilever flaps of microphone 101 can be coupled to an audio input of processing circuit 102 via a microphone output. The audio output of processing circuit 102 can be coupled to device 103 and can provide a processed audio output (e.g., digital signal representing audio sensed by microphone 101) to device 103.

In at least one example, processing circuit 102 comprises (or is part of) an integrated circuit which includes logic and or circuit to convert the audio input in an analog or acoustic domain (e.g., an analog signal) to the audio output in a digital domain or electrical domain (e.g., digital signal). Device 103 is any suitable client that uses the audio output from audio device 104. Examples of device 103 include a smart device, a smart phone, a tablet, an electric vehicle, a wearable device, a computer, etc.

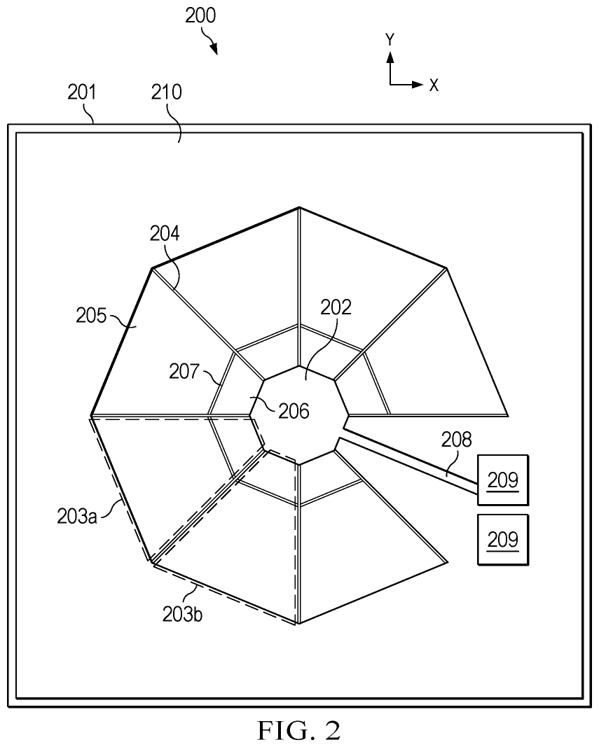

FIG. 2 is a schematic illustrating a top view of a transducer 200 with tapered cantilevers, in accordance with at least one example. Transducer 200 can be part of microphone 101 or a speaker. In at least one example, transducer 200 comprises a substrate 201 (e.g., a silicon-based substrate), a post 202 that is part of substrate 201, and a plurality of tapered cantilevers (e.g., cantilevers 203a and 203b) each including piezoelectric layers and electrodes. In some examples, transducer 200 includes piezoelectric layers 210 on substrate 201. Adjacent or neighboring cantilevers are separated by a gap 204. Gap 204 allows cantilevers to independently move as sound waves interact with the cantilevers, or as cantilevers vibrate to generate sound waves. In at least one example, an individual cantilever (e.g., cantilever 203a) includes a first flap portion 205, a second flap portion 206, and a discontinuity 207, where discontinuity 207 is in the electrodes on first flap portion 205 and second flap portion 206. Upon interaction with sound waves, first flap portion 205 develops motion which is perpendicular to the plane of the individual cantilever (e.g., motion is in a z-direction while the plane is in the x-y direction). The motion from first flap portion 205 is converted into electrical signal(s) on second flap portion 206, which has an edge attached to post 202. In at least one example, gap 204 provides a medium for transduction of motion from first flap portion 205 to electrical signal on second flap portion 206. Flap portions 205 and 206 can also vibrate response to electrical signals.

In at least one example, second flap portion 206 has a first edge which is shorter than the opposing edge of first flap portion 205, resulting in a tapered cantilever. With the first edge (e.g., shorter edge) coupled to (and anchored to) post 202, and the second edge movable, the tapered cantilever produces stress amplification which allows microphone 101 (or other transducer devices) to have a smaller area to produce the same SNR or the same amount of movement for a given applied voltage as a non-tapered cantilever transducer having a much larger area.

In at least one example, interconnect or electrode 208 is routed to an area or region reserved for a tapered cantilever. Interconnect or electrode 208 can be coupled to one or more pads 209 (e.g., metal pads), which in turn are connected to the microphone output. As discussed with reference to FIG. 1, the microphone output is connected to an audio input of processing circuit 102, in accordance with at least one example. While microphone 101 illustrates seven tapered cantilevers with respective second flap portions attached to post 202, any number of tapered cantilevers can be attached to post 202 in a polygon configuration.

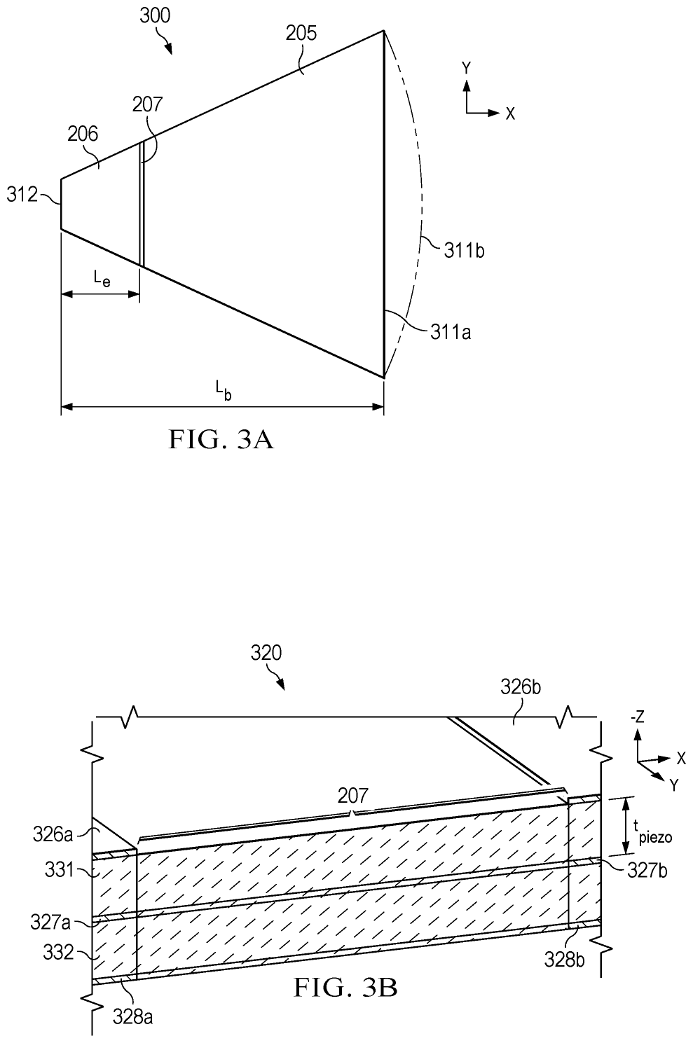

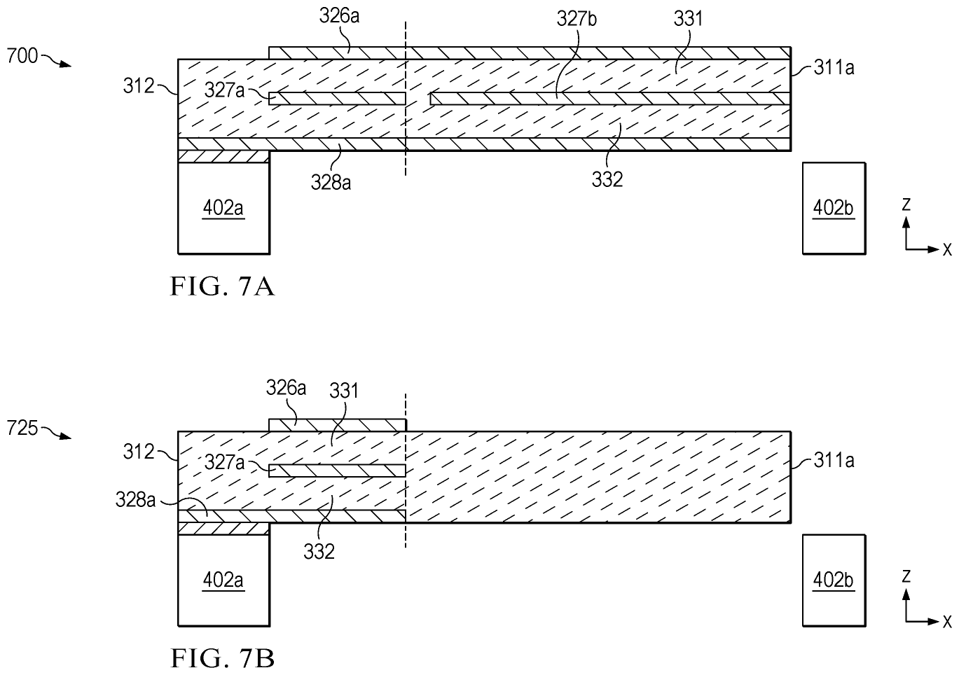

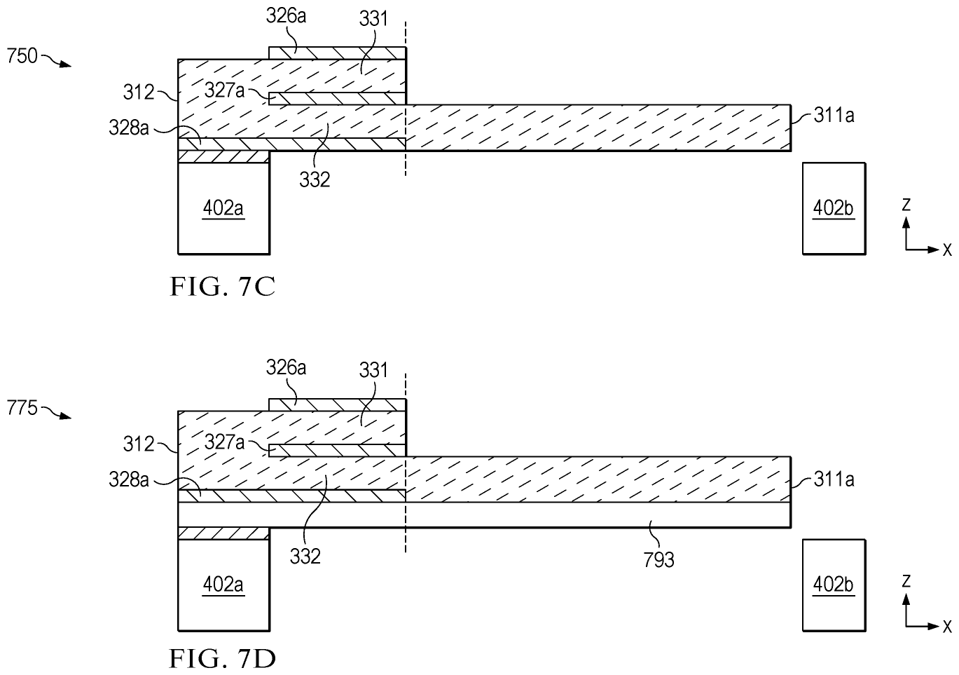

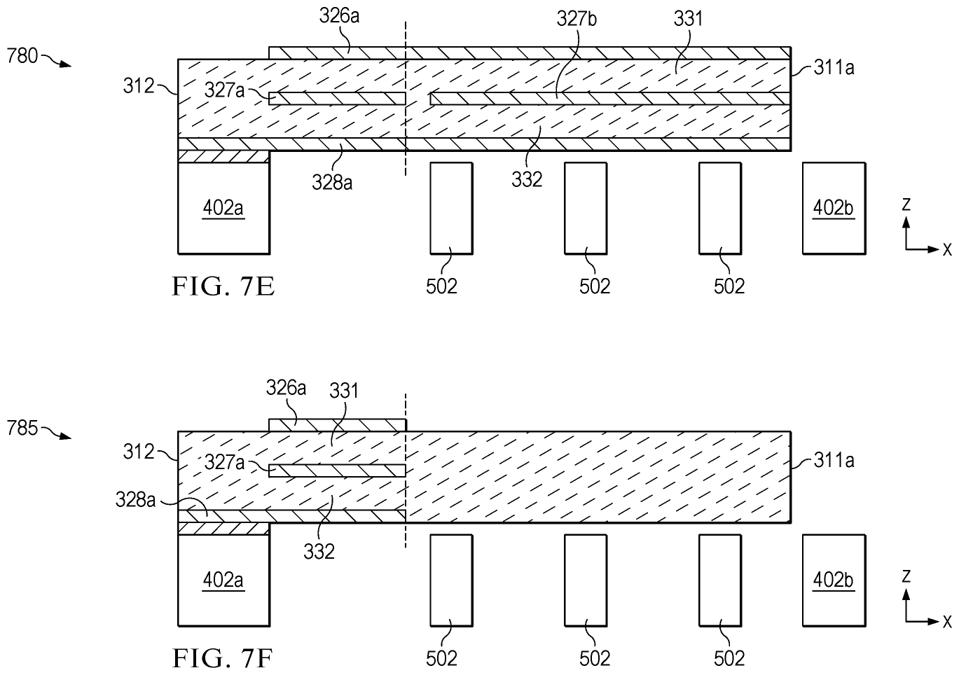

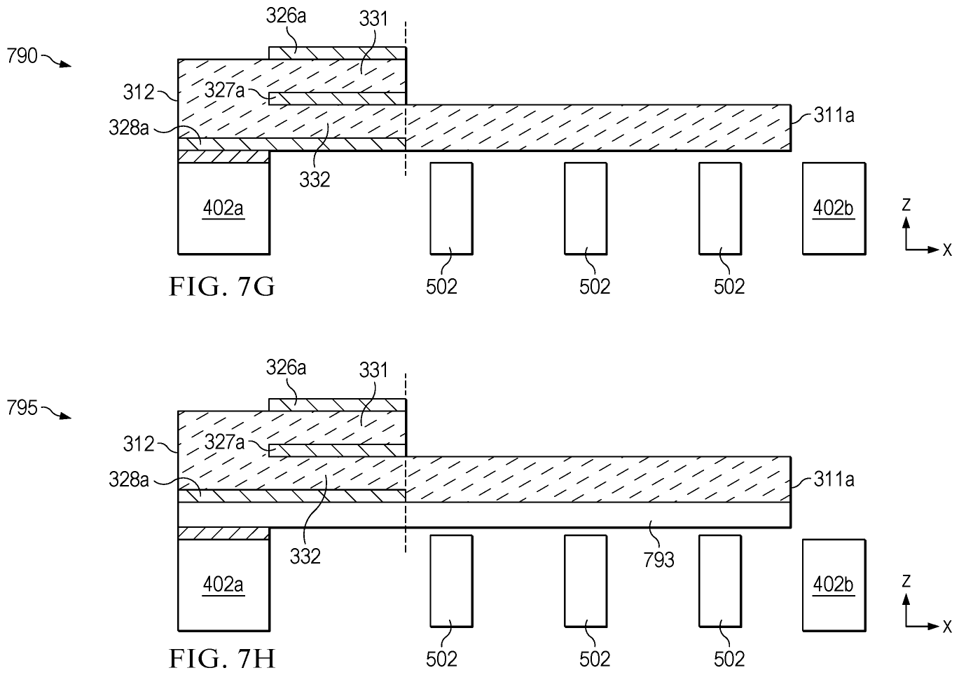

FIG. 3A is a schematic illustrating a top view of a flap 300 of a tapered cantilever (e.g., cantilever 203a), in accordance with at least one example. In at least one example, flap 300 has a first flap portion 205, second flap portion 206, gap 207, second edge 311a, and first edge 312. Length Le is the length from first edge 312 to gap 207 while length Lb (e.g., in a range from 150 μm to 350 μm) is the total length of flap 300 from first edge 312 to second edge 311a. First edge 312 is shorter than second edge 311a to form a tapered cantilever. Second edge 311a can be straight or curved. Other shapes or configurations for second edge 311a may be used to adjust mass loaded and/or area of first flap portion 205 which is exposed to sound waves. In at least one example, second edge 311a is a curved surface such as second edge 311b. While the top view of flap 300 (e.g., a bimorph cantilever) illustrates metal surfaces for first flap portion 205 and second flap portion 206, first flap portion 205 may not have a metal surface or electrode. Various configurations of bimorph cantilevers are illustrated with reference to FIGS. 7A-H.

In at least one example, flap 300 is a MEMS or a NEMS, which is fabricated within micron or nanometer dimensions, respectively. Certain MEMS or NEMS technologies may provide several benefits, such as batch fabrication that may lower manufacturing costs, small feature sizes, high resonant frequencies, and improved impedance matching.

FIG. 3B is a schematic illustrating cross-sectional view 320 of the flap of the tapered cantilever, in accordance with at least one example. In at least one example, second flap portion 206 of the tapered cantilever comprises top electrode 326a, middle electrode 327a, bottom electrode 328a, first piezoelectric layer 331, and second piezoelectric layer 332. First piezoelectric layer 331 is between top electrode 326a and middle electrode 327a. Second piezoelectric layer 332 is between middle electrode 327a and bottom electrode 328a. In at least one example, first flap portion 205 of the tapered cantilever comprises top electrode 326b, middle electrode 327b, bottom electrode 328b, first piezoelectric layer 331, and second piezoelectric layer 332. First piezoelectric layer 331 is between top electrode 326b and middle electrode 327b. Second piezoelectric layer 332 is between middle electrode 327b and bottom electrode 328b. Gap 207 separates first flap portion 205 from second flap portion 206. In at least one example, first piezoelectric layer 331 has a thickness along a z-direction of t_{piezo}. First piezoelectric layer 331 and second piezoelectric layer 332 can have the same thickness or can have different thicknesses.

In at least one example, first piezoelectric layer 331 and second piezoelectric layer 332 comprise aluminum nitride (AlN). The thickness of AlN can be configured based on the target performance of the tapered cantilever. For example, the thickness of AlN is substantially in a range of 200 nm to 500 nm to maximize SNR and sensitivity. While the examples are discussed with reference to AlN, any suitable piezoelectric material may be used. Vibrations from bending of first piezoelectric layer 331 and second piezoelectric layer 332 are converted into electrical signal(s) on the electrodes of the cantilever. In at least one example, one or more electric terminals are coupled to the electrodes of a cantilever and connected to a sense line which in turn is received by processing circuit 102.

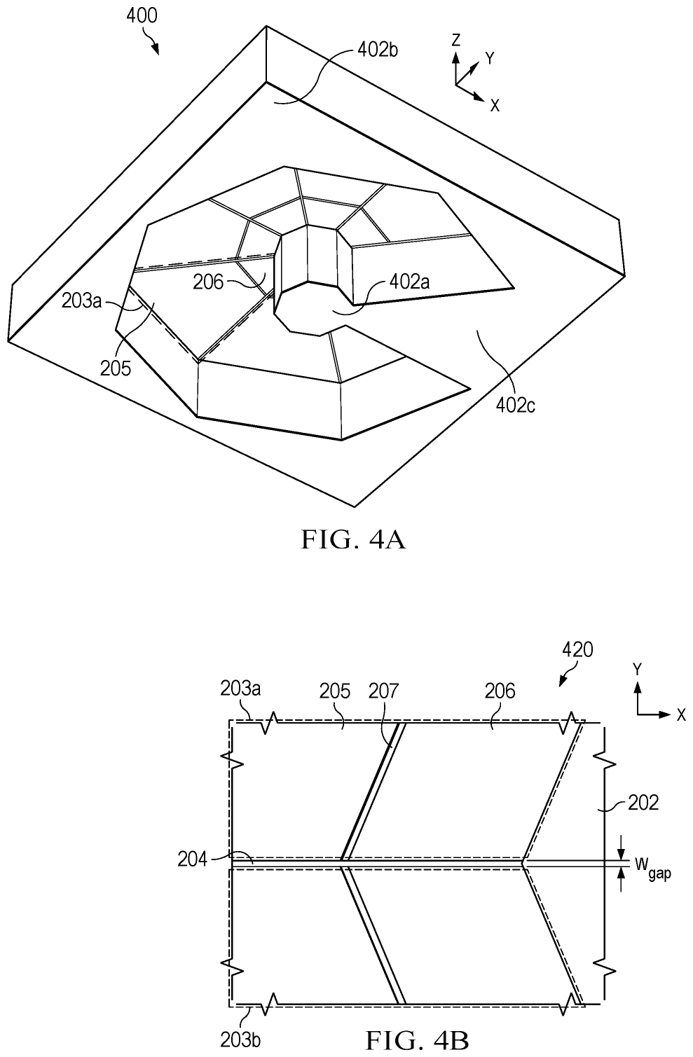

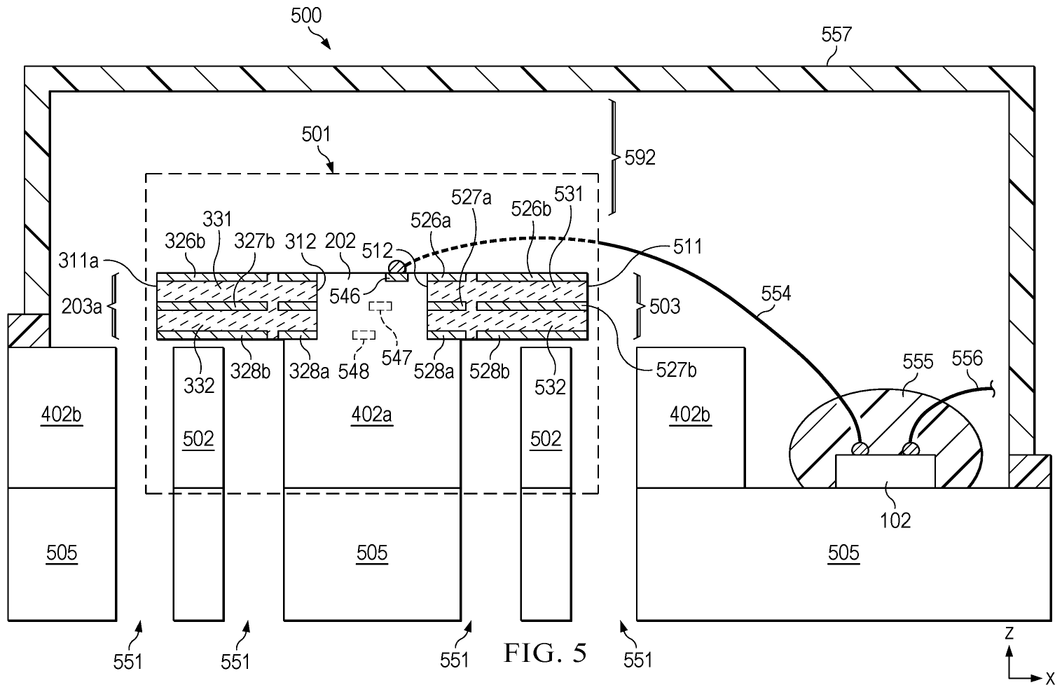

FIG. 4A is a schematic illustrating a three-dimensional (3D) view of a transducer 400 with tapered cantilevers, in accordance with at least one example. In at least one example, transducer 400 comprises substrate 201 (e.g., silicon-based substrate) having an opening through the substrate. In at least one example, substrate 201 includes a post portion 402a, a peripheral portion 402b, and an extension portion 402c. Piezoelectric layers 210 (not shown in FIG. 4A) can be on at least parts of post portion 402a, peripheral portion 402b, and extension portion 402c. Substrate 201 can be on another substrate, such as a printed circuit board (PCB). In at least one example, peripheral portion 402b is on a periphery of post portion 402a and connected to post portion 402a via extension portion 402c. In at least one example, post portion 402a and extension portion 402c abut the opening that allows sound waves to interact with the plurality of tapered cantilevers operating as a microphone, or allow sound waves generated by the plurality of tapered cantilevers operating as a speaker to propagate away from transducer 400. In some examples, transducer 400 includes piezoelectric layers on post portion 402a, peripheral portion 402b, and extension portion 402c.

In at least one example, the plurality of tapered cantilevers includes first tapered cantilever 203a having first edge 312 and second edge 311a (or second edge 311b), wherein first edge 312 is opposite to second edge 311a. First edge 312 can be on (and coupled to) the substrate (e.g., post portion 402a), and at least part of second edge 311a can be suspended over the opening, with second edge 311a longer than first edge 312.

In at least one example, the plurality of tapered cantilever includes a second tapered cantilever (e.g., cantilever 203b) similar to first tapered cantilever 203a. The second tapered cantilever includes a third edge and a fourth edge, wherein the third edge is opposite to the fourth edge, wherein the third edge is on the substrate, and wherein at least part of the fourth edge is suspended over the opening, the fourth edge being longer than the third edge. In at least one example, first edge 312 and second edge 311a are on (and anchored to) post portion 402a. In at least one example, while shown away from extension portion 402c, first tapered cantilever 203a is adjacent to extension portion 402c. In at least one example, first tapered cantilever 203a includes first electrodes (e.g., top electrodes 326a, 326b, middle electrodes 327a, 327b, and bottom electrodes 328a, 328b). Second tapered cantilever 203b can also have similar structure as first tapered cantilever 203a and includes second electrodes. In at least one example, transducer 400 includes metal interconnects (e.g., electrode 208) on extension portion 402c, wherein the metal interconnects electrically couple between the first and second electrodes and metal pads 209 on peripheral portion 402b.

Here, stress enhancement or amplification is achieved by anchoring shorter edges of tapered cantilevers to post portion 402a of the substrate. Stress enhancement or amplification improves the performance of transducer 400 as the SNR improves. In at least one example, post portion 402a provides an additional mechanical rigidity to transducer 400 and makes handling of dies with such microphones easier to handle during fabrication. By anchoring shorter edges of the plurality of tapered cantilevers to post portion 402a, the area of transducer 400 can be reduced as shorter or smaller tapered cantilevers can be used because of stress amplification.

FIG. 4B is a schematic 420 illustrating a zoomed view showing two adjacent flaps of the tapered cantilevers, in accordance with at least one example. Schematic 420 illustrates a gap having width Wgap (e.g., in a range of 0.5 μm to 3 μm) between neighboring tapered cantilevers 203a and 203b. The dimension of Wgap is selected at design phase to adjust resonant frequency of transducer 400.

FIG. 5 is a schematic illustrating a cross-section of an audio system 500 including a transducer device having tapered cantilevers, in accordance with at least one example. In at least one example, audio system 500 includes a transducer device 501, which can be microphone 101 or a speaker, and processing circuit 102 on a substrate 505 (e.g., PCB). Transducer device 501 includes a cantilever system comprising bimorph tapered piezoelectric cantilevers 203a and 503 on a semiconductor structure or post portion 402a, and openings 551. In at least one example, a first set of electrodes (including to top electrode 326a, middle electrode 327a, and bottom electrode 328a) of bimorph tapered piezoelectric cantilever 203a is attached to or coupled to post portion 402a of the substrate. In at least one example, a second set of electrodes (including to top electrode 526a, middle electrode 527a, and bottom electrode 528a) of bimorph tapered piezoelectric cantilever 503 is attached to or coupled to post portion 402a of the substrate. Bimorph tapered piezoelectric cantilever 503 is like bimorph tapered piezoelectric cantilever 203a and is positioned symmetrically opposite to bimorph tapered piezoelectric cantilever 203a. In at least one example, a first piezoelectric layer 531 is between top electrode 526b and middle electrode 527b, and a second piezoelectric layer 532 is between middle electrode 527b and bottom electrode 528b.

In at least one example, the thickness (in the z-direction) of first piezoelectric layer 331 (and 531) is the same as the thickness (in the z-direction) of second piezoelectric layer 332 (and 532). In at least one example, the thickness (in the z-direction) of first piezoelectric layer 331 (and 531) is different from the thickness (in the z-direction) of second piezoelectric layer 332 (and 532). By changing thickness and/or material composition of first piezoelectric layer 331 (and 531) relative to second piezoelectric layer 332 (and 532), the sensitivity and/or resonant frequency of piezoelectric bimorph cantilevers 203a and 503 can be modified. Different cantilever material stack configurations can be used for tailoring stiffness and hence sensitivity of the cantilever.

In at least one example, post portion 402a has metal contacts 546, 547, and 548 to couple to top electrode 326a, middle electrode 327a, and bottom electrode 328a, respectively. Metal contacts 546, 547, and 548 may be embedded in post portion 402a and coupled to one or more wires 554. In at least one example, metal contacts 546, 547, and 548 are on top of post portion 402a and couple to one or more wires 554.

In at least one example, first edge 312 (e.g., shorter edge) of bimorph tapered piezoelectric cantilever 203a and first edge 512 of bimorph tapered piezoelectric cantilever 503 are attached, clamped, or coupled to post portion 402a. Second edge 311a (e.g., longer edge) of bimorph tapered piezoelectric cantilever 203a and second edge 511 of bimorph tapered piezoelectric cantilever 503 can hang over optional truss portion 502 and interact with sound waves coming through opening 551.

In at least one example, opening 551 extends from post portion 402a to peripheral portion 402b. In at least one example, opening 551 is between post portion 402a and truss portion 502, where truss portion 502 is part of substrate 505.

In at least one example, the electrodes of cantilevers 203a and 503, and piezoelectric layers 331, 332, 531, and 532 comprise material(s) compatible with certain CMOS processing. In at least one example, the electrodes of cantilevers 203a and 503 comprise molybdenum (Mo or “moly”, or any other suitable material for electrodes). In at least one example, piezoelectric layers 331, 332, 531, and 532 comprise aluminum nitride (“AlN”) or any other suitable piezoelectric material.

In at least one example, audio system 500 further includes an integrated circuit or processing circuit 102 which is encapsulated in epoxy 555. One or more wire(s) 554 (e.g., bond wires) electrically couple between processing circuit 102 and transducer device 501. In at least one example, audio system 500 includes one or more wire(s) 556 (e.g., bond wires) that electrically couple integrated circuit or processing circuit 102 to device 103. In at least one example, integrated circuit or processing circuit 102 is attached to substrate 505 (e.g., PCB). In at least one example, post portion 402a, peripheral portion 402b, extension portion 402b, and truss portion 502 are over portions of substrate 505 as shown. In at least one example, audio system 500 further includes a case or package 557 that encloses integrated circuit or processing circuit 102, bimorph tapered piezoelectric cantilevers, and back volume space 592.

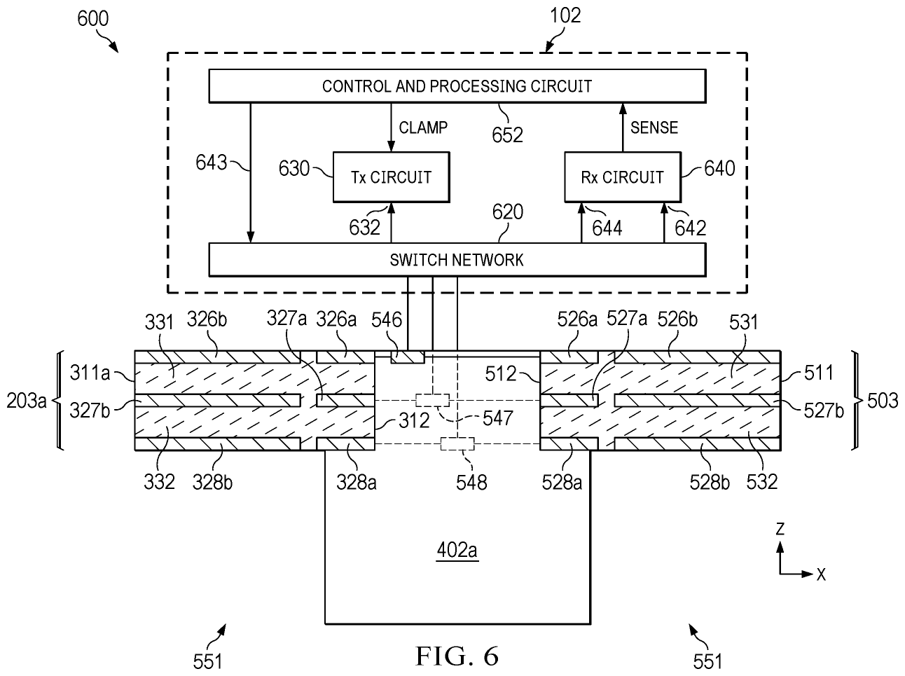

FIG. 6 is a schematic illustrating a processing circuit, such as processing circuit 102, coupled to tapered cantilevers that are anchored to a post, in accordance with at least one example. In at least one example, processing circuit 102 can be coupled to bimorph tapered piezoelectric cantilevers (including cantilever 203a and cantilever 503. The bimorph tapered piezoelectric cantilevers can be part of microphone 101, a speaker, a stress sensor, an accelerometer, etc.

In at least one example, processing circuit 102 includes switch network 620, transmitter (Tx) circuit 630, receiver (Rx) circuit 640, and control and processing circuit 652.

In at least one example, terminals from switch network 620 couple to metal contacts 546, 547, and 548. As discussed herein, metal contacts 546, 547, and 548 can be in or on peripheral portion 402b or post portion 402a. In at least one example, terminals, wires, or interconnect (e.g., electrode 208) from switch network 620 can include any suitable electrical connector to transfer electrical current. In at least one example, the terminals electrically couple bimorph tapered piezoelectric cantilevers 203a and 503 to Rx circuit 640.

In at least one example, Rx circuit 640 includes circuit that receives electrical signals at receiver inputs 642 and 644. Electrical signals at receiver inputs 642 and 644 can represent an electric field between electrodes 326a, 327a, and 328a for bimorph tapered piezoelectric cantilever 203a. Electrical signals at receiver inputs 642 and 644 can represent an electric field between electrodes 526a, 527a, and 528a for bimorph tapered piezoelectric cantilever 503. The electric field between the electrodes reflects a stress in bimorph tapered piezoelectric cantilevers 203a and 503 caused by the sound waves.

In at least one example, Rx circuit 640 provides corresponding electrical signals (e.g., sense signal) to control and processing circuit 652. Bimorph tapered piezoelectric cantilever 203a can vibrate responsive to soundwaves, resulting in stress that is converted into an electrical signal that is provided to Rx circuit 640 via inputs 642 and 644. Rx circuit 640 can also perform a conversion operation on received electrical signals. In at least one example, Rx circuit 640 performs an analog-to-digital conversion that involves receiving analog electrical signals at receiver inputs 642 and 644 and converting the received analog electrical signals to digital electrical signals. Rx circuit 640 provides converted digital electrical signals to control and processing circuit 652. In at least one example, Rx circuit 640 provides analog signals to control and processing circuit 652. In at least one example, control and processing circuit 652 converts received analog circuits to digital signals using an internal analog-to-digital converter and provides an output to device 103. In at least one example, each bimorph tapered piezoelectric cantilever may have an associated receiver circuit. In at least one example, the plurality of bimorph tapered piezoelectric cantilevers share the same receiver circuit.

In at least one example, processing circuit 102 includes Tx circuit 630 which comprises circuit that receives a clamp signal (or a disable signal) from control and processing circuit 652. Responsive to the clamp signal, Tx circuit 630 can transmit a DC voltage on its output 632 to switch network 620. Tx circuit 630 can apply the DC voltage across top electrode 326a and bottom electrode 328a, or between bottom electrode 328a and truss portions 502, to set the initial states of cantilevers 203a and 503 by flattening or otherwise countering the bending of the cantilevers due to residual stress. Applying a voltage between top electrode 326a and bottom electrode 328a can generate a piezoelectric force to counter the residual stress, while applying a voltage between bottom electrode 328a and truss 502 can generate an electrostatic force to counter the residual stress. In at least one example, switch network 620 may operate as a transmitter or receiver of signals based on logic polarity of control 643. In some examples, control and processing circuit 652 can operate the tapered piezoelectric cantilevers as a speaker, and provide audio signals to the tapered piezoelectric cantilevers via TX circuit 630 to generate sound waves.

FIGS. 7A, 7B, 7C, 7D, 7E, 7F, 7G, and 7H are schematics illustrating cross-sections of piezoelectric bimorph tapered cantilevers 700, 725, 750, 775, 780, 785, 790, and 795, respectively, according to some examples. Any configuration of piezoelectric bimorph tapered cantilevers 700, 725, 750, 775, 780, 785, 790, and 795 may be used for microphone 101. Here, dashed line indicates separation of first flap portion 205 and second flap portion 206, where second flap portion 206 is attached to post portion 402a.

In at least one example, with reference to piezoelectric bimorph tapered cantilever 700, top electrode 326a extends to second edge 311a. In at least one example, a discontinuity is present between middle electrode 327a and middle electrode 327b. In at least one example, bottom electrode 328a extends from first edge 312 to second edge 311a and couples to post portion 402a. In at least one example, a DC bias or voltage is applied between bottom electrode 328a and peripheral portion 402b. In at least one example, there is an opening between post portion 402a and peripheral portion 402b, where the opening allows sound waves to interact with piezoelectric bimorph tapered cantilever 700.

In at least one example, with reference to piezoelectric bimorph tapered cantilever 725, top electrode 326a, middle electrode 327a, and bottom electrode 328a are in second flap portion 206. In this configuration, first flap portion 205 has no electrodes and comprises a bulk piezoelectric material.

In at least one example, with reference to piezoelectric bimorph tapered cantilever 750, top electrode 326a, middle electrode 327a, and bottom electrode 328a are in second flap portion 206. In this configuration, first flap portion 205 has no electrodes and comprises second piezoelectric layer 332.

In at least one example, with reference to piezoelectric bimorph tapered cantilever 775, top electrode 326a, middle electrode 327a, and bottom electrode 328a are in second flap portion 206. In this configuration, first flap portion 205 has no electrodes and comprises second piezoelectric layer 332. In at least one example, an additional layer 793 of the substrate is formed between post portion 402a and bottom electrode 328a and piezoelectric layer 332. In at least one example, additional layer 793 of the substrate extends from first edge 312 to second edge 311a.

Piezoelectric bimorph tapered cantilevers 780, 785, 790, and 795 are like piezoelectric bimorph tapered cantilevers 700, 725, 750, and 775, but with one or more truss portions 502 under first flap portion 205. In at least one example, DC actuation voltage or bias can be applied between bottom electrode 312a and truss portion 502 to clamp or park piezoelectric bimorph cantilevers down to the trusses. In at least one example, clamping the piezoelectric bimorph cantilevers prevents interference to the operation of microphone 101 with other sensors or microphones in case or package 557 through back volume acoustic coupling. Different cantilever material stack configurations can be used for tailoring stiffness and hence sensitivity of the cantilever.

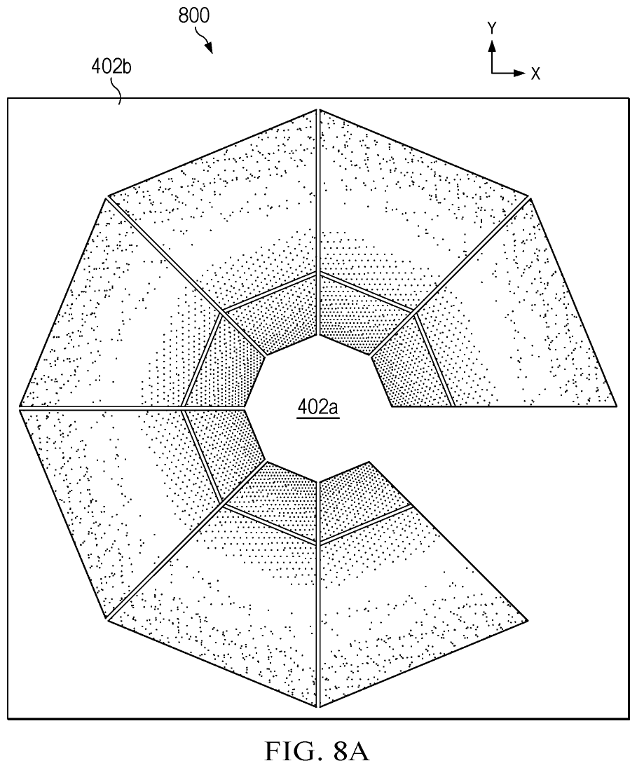

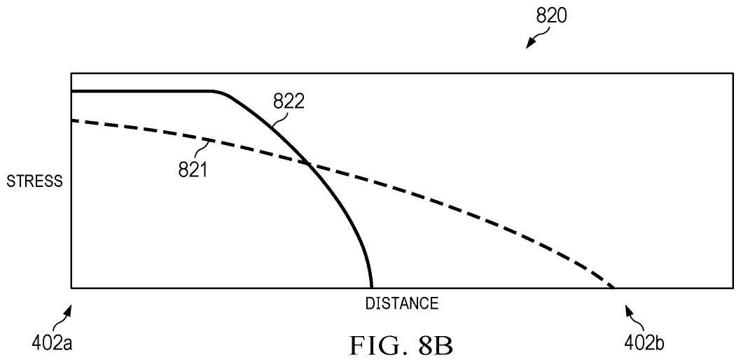

FIG. 8A is a schematic 800 illustrating stress along direction of length of a tapered cantilever structure, in accordance with at least one example. Schematic 800 of microphone 101 illustrates that maximum stress concentration on tapered cantilevers is near post portion 402a. This stress concentration is higher than other configurations of tapered cantilevers that do not have post portion 402a at the center to which to attach. Incoming audio in the frequency band of interest causes the tapered and trapezoidal cantilevers to bend. In at least one example, bimorph neutral axis remains unaffected by the change in shape of tapered cantilevers from a triangular shape to tapered trapezoidal shape.

FIG. 8B is a plot 820 illustrating stress as a function of distance from post portion 402a for tapered and non-tapered cantilevers, in accordance with at least one example. Plot 820 illustrates graphs 821 and 822. For microphones using non-tapered cantilevers, concentration of stress falls steadily over the length of the cantilever as shown by waveform 821. For tapered cantilevers anchored to post portion 402a, the stress near post portion 402a (where distance is small) is higher than the stress of the non-tapered cantilevers. Also, the stress of tapered cantilevers rolls off faster, hence stress concentration can be maximized at and near post portion 402a and remains flat for a longer distance before falling off near peripheral portion 402b. This allows the cantilever electrode to be shortened, yet the shortened cantilever electrode can still sense the electric field corresponding to the maximum stress. In at least one example, the length Le of a cantilever electrode as a fraction of cantilever length Lb is set to a particular ratio (e.g., in a range of 0.25 to 0.5) to increase/maximize the electromagnetic coupling (and the efficiency of transduction) of the cantilever.

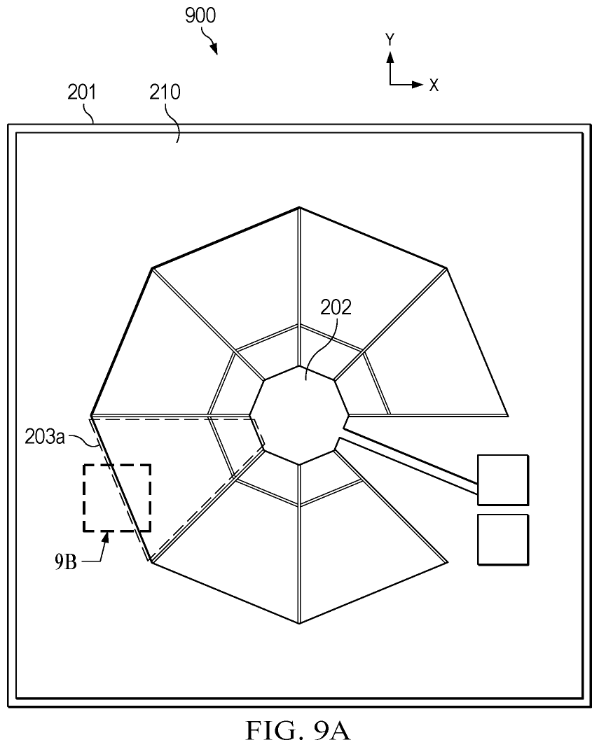

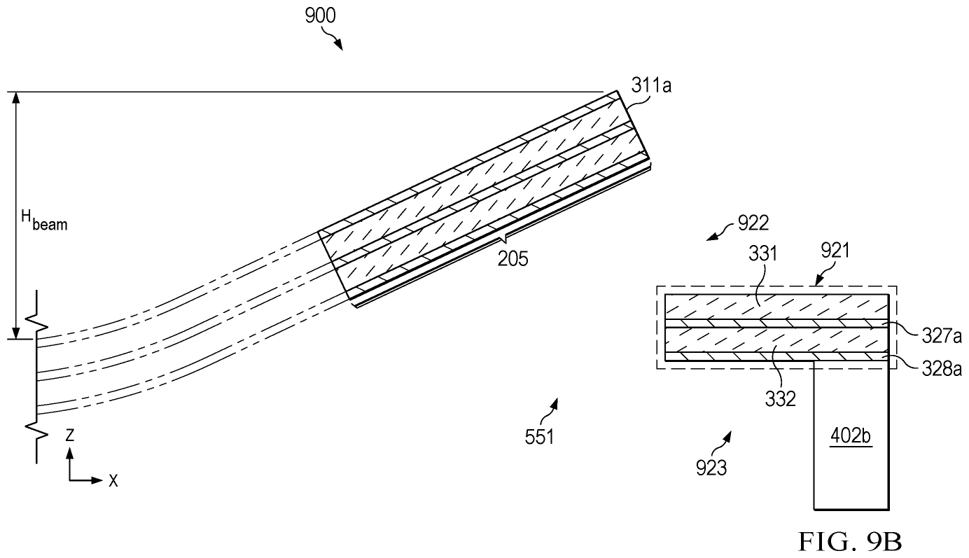

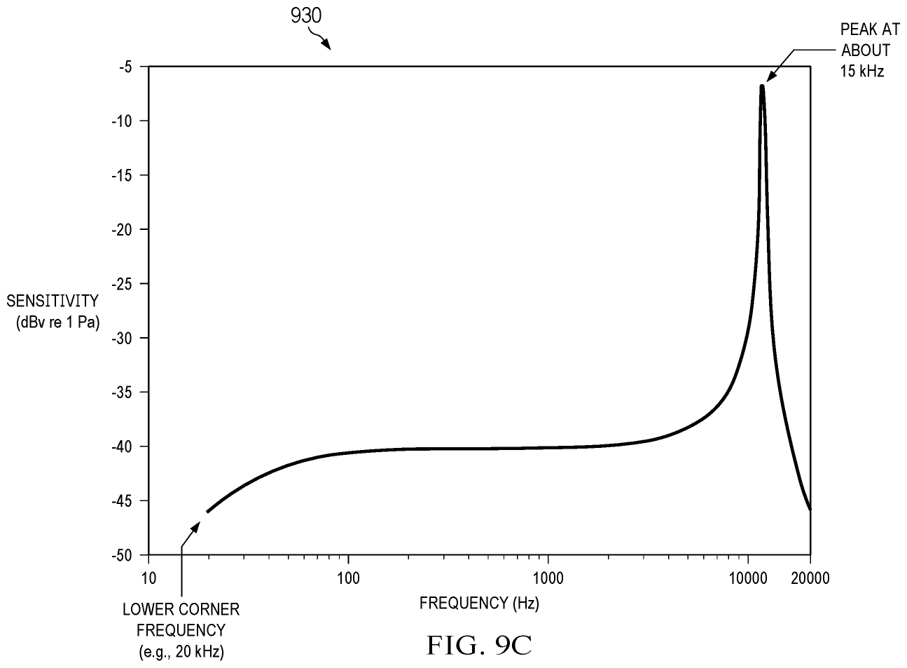

FIG. 9A is a schematic illustrating a top view of a transducer 900 with tapered cantilever, and FIG. 9B is a schematic illustrating a side view of transducer 900, in accordance with at least one example. Transducer 900 can be part of microphone 101, a speaker, etc. Schematic 900 has similar features as the schematic of transducer 200. In some cases, first flap portion 205 near second edge 311a of cantilever 203a may deflect up by distance H_{beam} along z-axis. Here, H_{beam} is the height relative to top portion of cantilever at first edge 312 anchored to post portion 402a and first flap portion 205 near second edge 311a. As described above, the cantilevers may have residual stress that cause the cantilever 203a to bend in the post-release state, and the cantilever 203a may bend up, and the second edge 311a have a height of H_{beam} above top portion of cantilever at first edge 312. The bending can increase gap 922 between second edge 311a and the piezoelectric layers 921 (which can be part of piezoelectric layers 210) on peripheral portion 402b of substrate 201, which can affect the lower corner frequency of transducer 900.

In at least one example, processing circuit 102 applies a voltage to cantilever 203a to flatten (or counter the upward bending of) first flap portion 205 near second edge 311a to prevent a reduction in ventilation resistance. In some examples, processing circuit 102 can perform a self-test operation. For example, referring again to FIG. 2, FIG. 5, and FIG. 6, processing circuit 102 can drive a subset of the cantilevers (e.g., cantilever 203a) of transducer 900 with an audio signal, and perform a frequency sweep of the audio signal, so that those cantilevers can generate sound waves at different frequencies. Processing circuit 102 can detect the sound waves using a different subset of cantilevers of transducer 900 and determine, for example, the amplitudes of the detected sound waves at different frequencies as a frequency response of transducer 900. Processing circuit 102 can then determine the lower corner frequency of the frequency response, and determine H_{beam} (or the size of opening 922) based on the lower corner frequency. Based on a difference between the lower corner frequency and a target lower corner frequency, processing circuit 102 can determine the voltage to be applied to the cantilevers in the post-release state to shrink H_{beam}.

FIG. 9C is a plot 930 illustrating sensitivity of a microphone having tapered cantilever microphone as a function of frequency, in accordance with at least one example. Plot 930 illustrates a largely flat sensitivity response to change in frequency for the tapered cantilever based microphone. Plot 930 can represent, for example, the frequency response of the transducer 900 generated by processing circuit 102 in the aforementioned self-test operation. Plot 930 indicates a sensitivity of −40 dBV within most the audible frequency range (e.g., between 100 to 20000 Hz), and a lower corner frequency of 20 Hz where the sensitivity reduces by 3 dB. Processing circuit 102 can determine a difference between the lower corner frequency of 20 Hz with a target lower corner frequency, and determine the voltage to be applied to the cantilevers in the post-release state based on the difference. Also, the frequency response peaks at about 15 kHz, and the processing circuit 102 can perform an equalization operation (e.g., based on the self-test operation results) near the peak frequency to improve the flatness of the frequency response around the peak frequency.

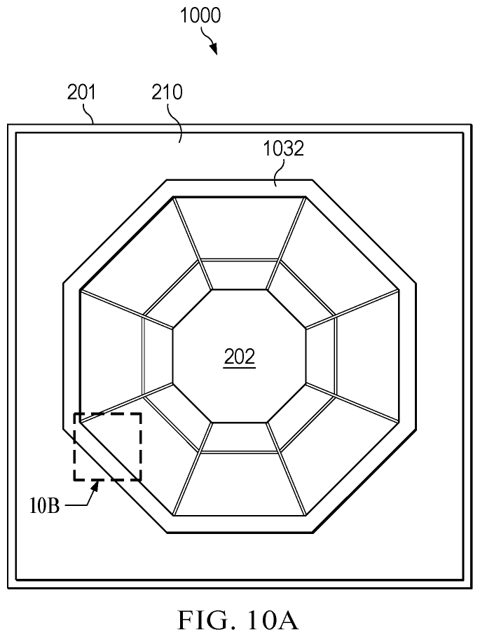

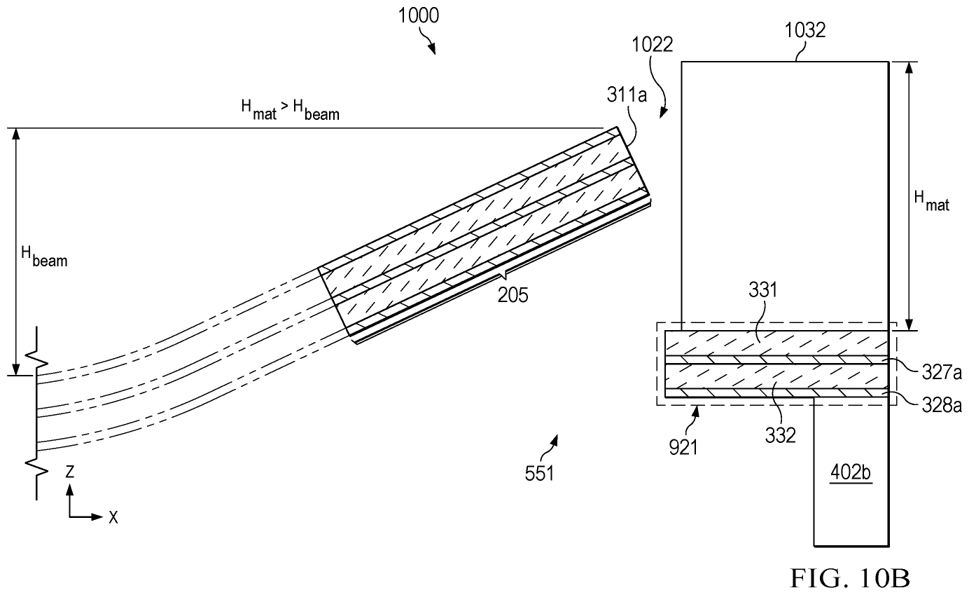

FIG. 10A is a schematic illustrating a top view of a microphone 1000 with tapered cantilever that is surrounded with a dam, in accordance with at least one example. In at least one example, the area of extension portion 402c is also used for a tapered cantilever coupled to post 202. In at least one example, a dam 1032 is formed along the outer edges (e.g., second edge 311a) of the plurality of cantilevers. Dam 1032 can reduce the separation between the outer edges of the cantilevers and piezoelectric layers 921 on peripheral portion 402b.

FIG. 10B is a schematic (e.g., portion 10B of FIG. 10A) illustrating a structure for stress and misalignment control near the outer edge of the tapered cantilever and the dam, according to at least one example. In at least one example, dam 1032 is formed over the piezoelectric layers 921 on peripheral portion 402b. Dam 1032 can be made of various materials, such as a dielectric material (e.g., silicon dioxide) and a metal. With dam 1032, the gap 1022 between the outer edge of the tapered cantilever and piezoelectric layers 921 on peripheral portion 402b even if the tapered cantilever bends upwards in its initial state due to residual stress, which can maintain the lower corner frequency of the microphone. Residual stress gradients can be engineered to ensure that the cantilever bends in the upward direction post-release. In some examples, height Hₘₐₜ of dam 1032 is selected to be higher than height H_{beam}, which indicates the level of upward deflection of first flap portion 205 near second edge 311a relative to the anchoring point at post portion 402a.

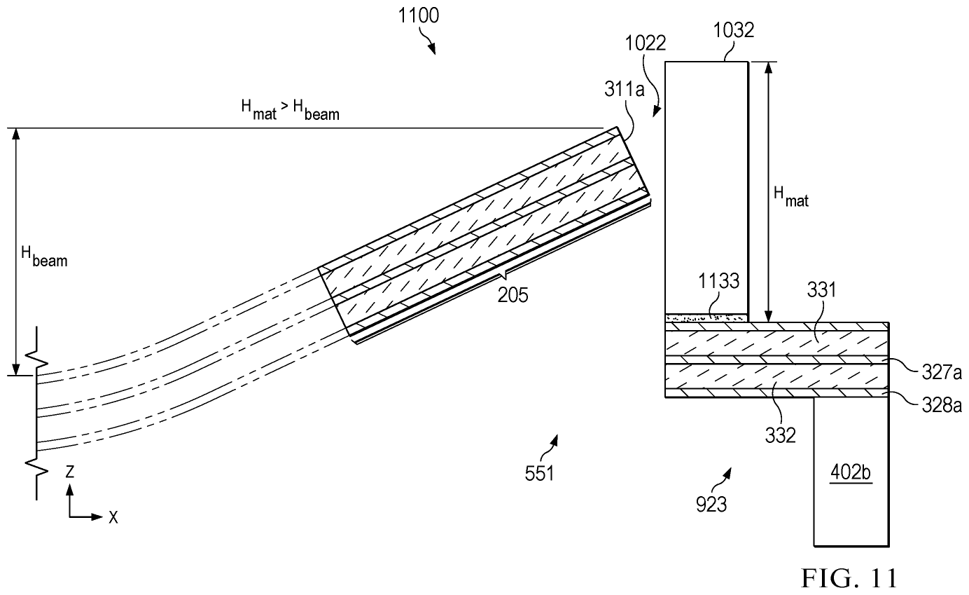

FIG. 11 is a schematic illustrating a structure 1100 for stress and misalignment control near the outer edge of the tapered cantilever and the dam, according to at least one example. In at least one example, dam 1032 can be made thinner as shown for dam 1132. In at least one example, dam 1132 is on layer 1133, which in turn is coupled to the top surface of piezoelectric layers 921. In some examples, dam 1132 can be metallic, and layer 1133 can be a seed layer for forming dam 1132.

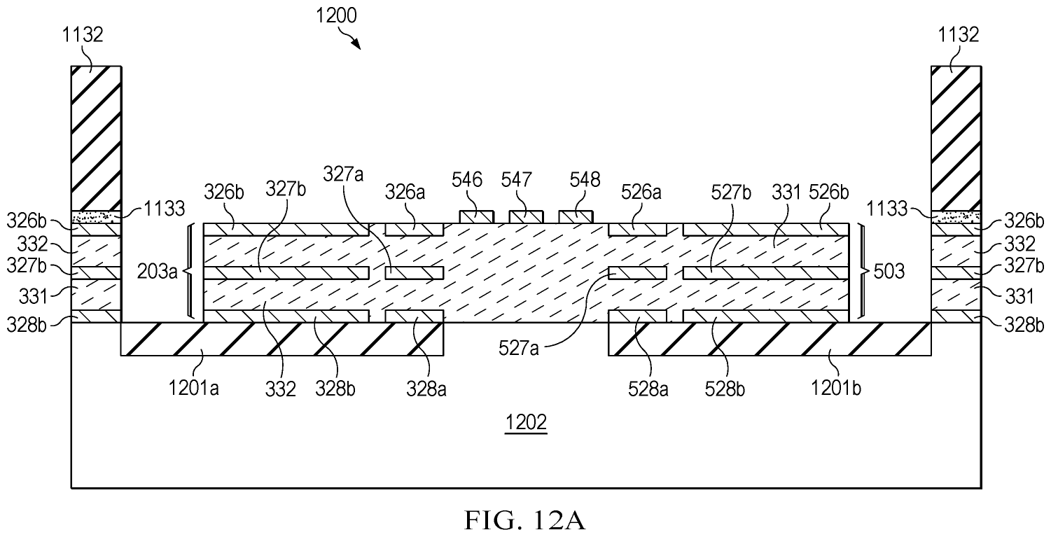

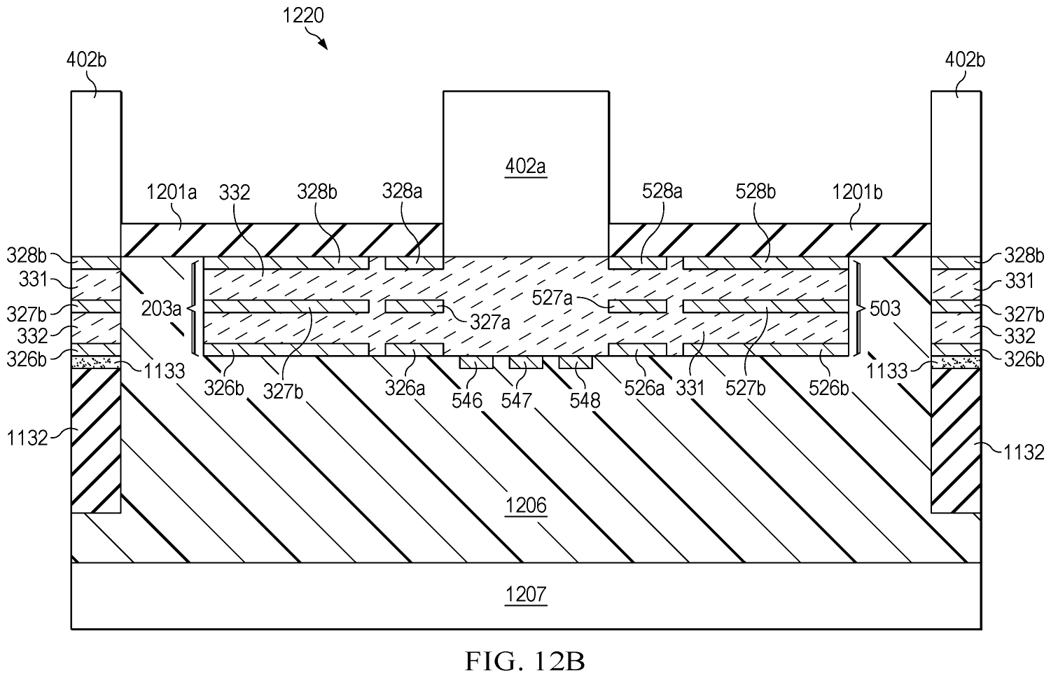

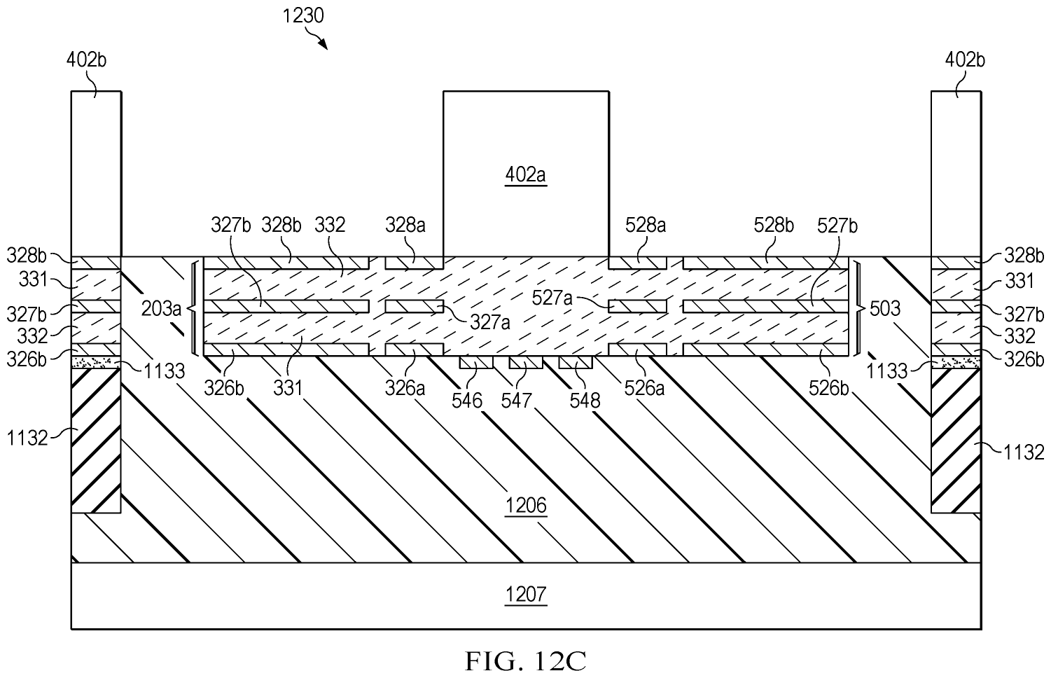

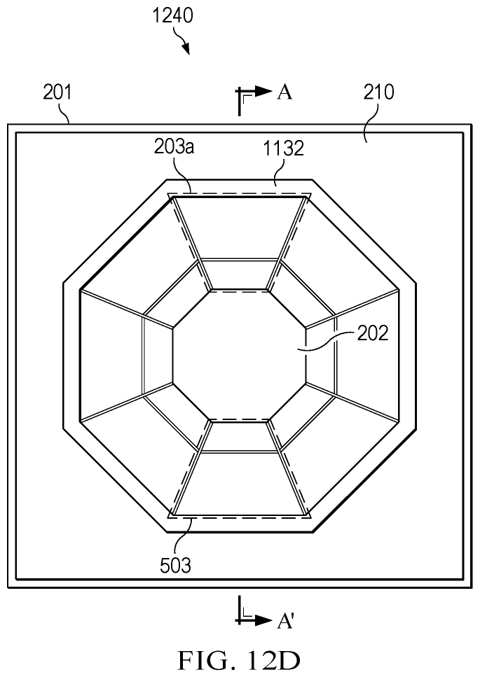

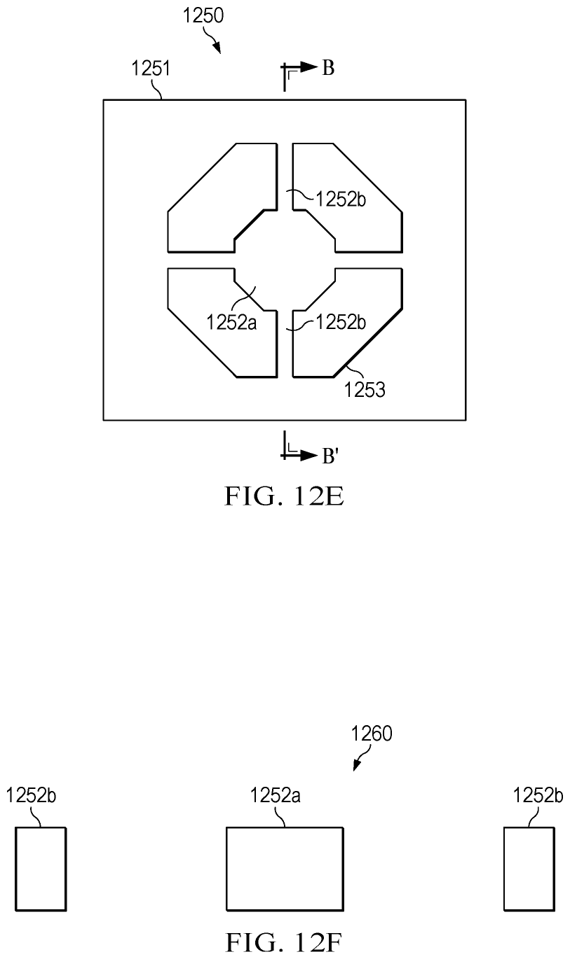

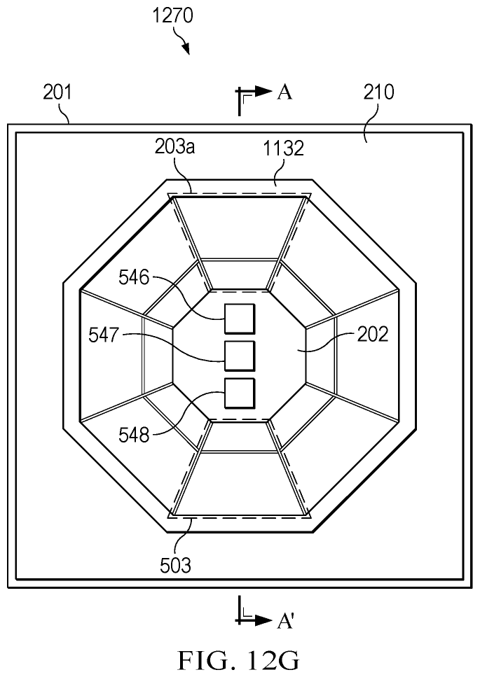

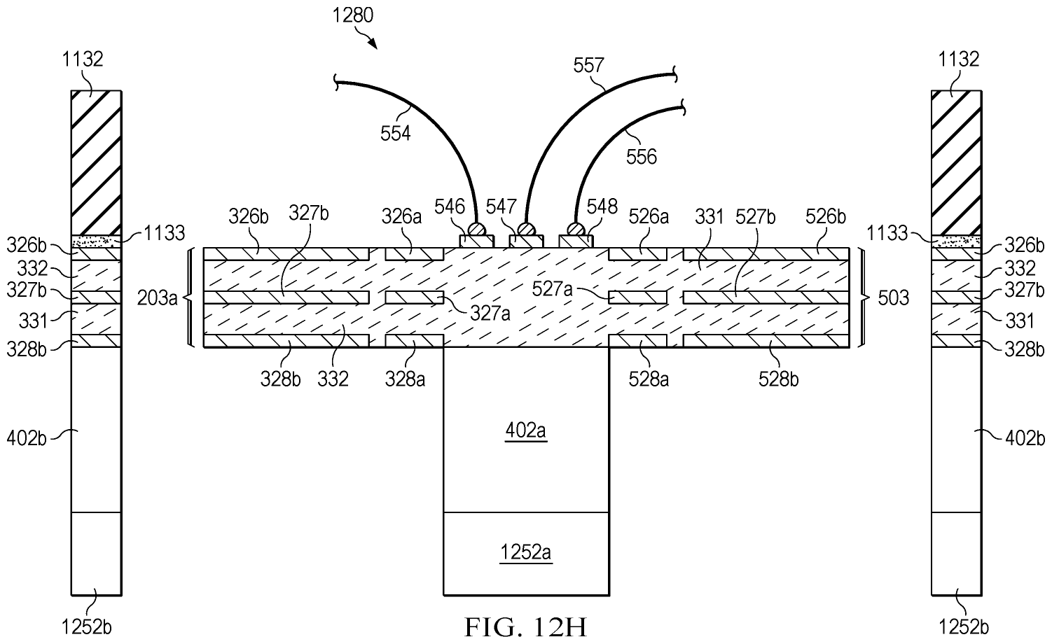

FIGS. 12A, 12B, 12C, 12D, 12E, 12F, 12G, and 12H are schematics 1200, 1220, 1230, 1240, 1250, 1260, 1270, and 1280, respectively, illustrating the process of fabricating a microphone with tapered cantilevers, in accordance with some examples. Schematic 1200 illustrates a cross-section of a microphone after dam 1132 (or dam 1032) is formed. Schematic 1200 illustrates etch stop layers 1201a and 1201b under bimorph tapered cantilevers 203a and 503, respectively. In at least one example, etch stop layers are used to form opening between post portion 402a and peripheral portion 402b.

Schematic 1220 illustrates a cross-section after substrate 1202 is etched up to etch stop layers 1201a and 1201b. Substrate 1202 is etched to form post portion 402a in the center and peripheral portion 402b on the periphery of bimorph tapered cantilevers 203a and 503. In at least one example, etch stop layers 1201a and 1201b are buried oxide layers. In at least one example, deep reactive ion etching (DRIE) is applied for etching substrate 1202 to form cavities or openings such as opening 551. The DRIE process can produce near vertical sidewalls and stops at etch stop layers 1201a and 1201b. Schematic 1220 further illustrates deposition of bonding material 1206 over a surface of tapered cantilevers 203a and 503. In at least one example, bonding material 1206 is deposited on an opposite surface of tapered cantilevers 203a and 503. Bonding material may cover dam 1132. Bonding material 1206 allows for adhesion with carrier 1207. In at least one example, carrier 1207 is a wafer. Examples of carrier 1207 include silicon, silicon carbide, glass, quartz, sapphire, and gallium arsenide. Examples of bonding material 1206 include acetone, n-methyl-2-pyrrolidone, or 1-methyl-2-pyrrolidone (NMP), 6N hydrochloric acid (6N HCl), Hydrogen peroxide (e.g., 15% H₂O₂), Ammonium Hydroxide (30% NH₄OH), Potassium Iodide in water (e.g., 10% Kl in H₂O), ethanol, methanol, isopropanol, cyclohexanone, ethyl lactate, Propylene glycol methyl ether acetate (PGMEA, 1-methoxy-2-propanol acetate), Propylene glycol methyl ether (PGME or 1-methoxy-2-propanol), 30% HCl, 70% Nitroxyl (HNO₃), Tetramethylammonium hydroxide (e.g., 0.26N TMAH or TMAOH), and Potassium hydroxide (e.g., 30% KOH).

Schematic 1230 illustrates cross-section of microphone 101 after etch stop layers 1201a and 1201b are removed allowing the opening to reach tapered cantilevers 203a and 503. In at least one example, hydrofluoric acid (HF) vapor release process is applied to remove etch stop layers 1201a and 1201b.

Schematic 1240 illustrates the top view of schematic 1230 showing dam 1132 around tapered cantilevers after HF vapor release process. In this example, an octagonal configuration of tapered cantilever is used to form the microphone. In at least one example, extension portion 402c is occupied by a taped cantilever instead of an opening used for interconnect of electrode 208.

Schematic 1250 illustrates the top view of a handle wafer 1251 which is sliced to form post portion 1252a and peripheral portion 1252b using mask 1253. Schematic 1260 illustrates the cross-sections of handle wafer 1251 after it is sliced to form post portion 1252a and peripheral portion 1252b.

Schematic 1270 illustrates a top view of microphone 101 after metal contacts 546, 547, and 548 are connected to wires or interconnect. Schematic 1280 illustrates a cross-section of the microphone after wires are connected or bonded to metal contacts 546, 547, and 548, and after post portion 1252a and peripheral portion 1252b from handle wafer 1251 are bonded to post portion 402a and peripheral portion 402b.

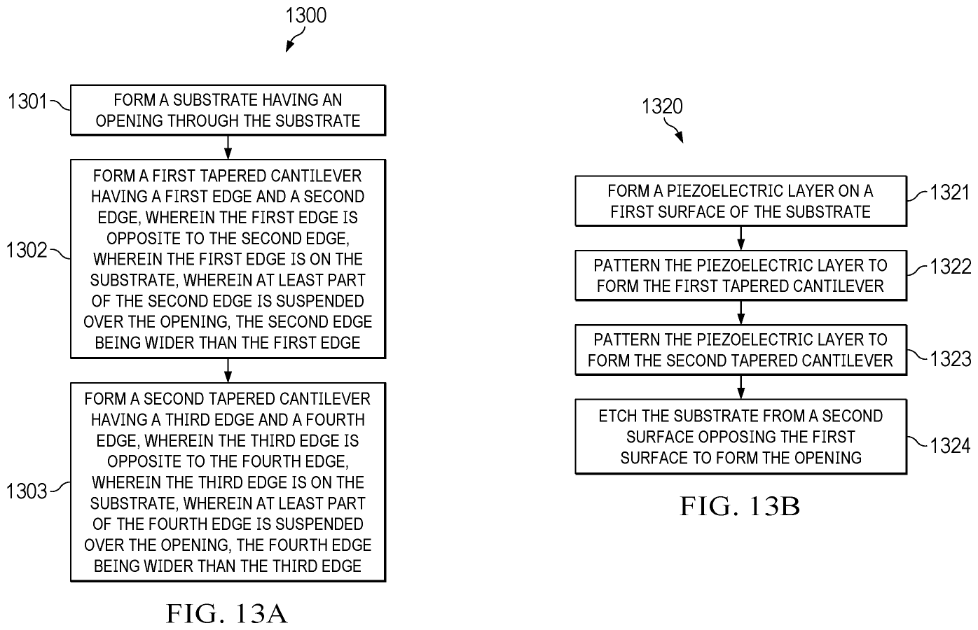

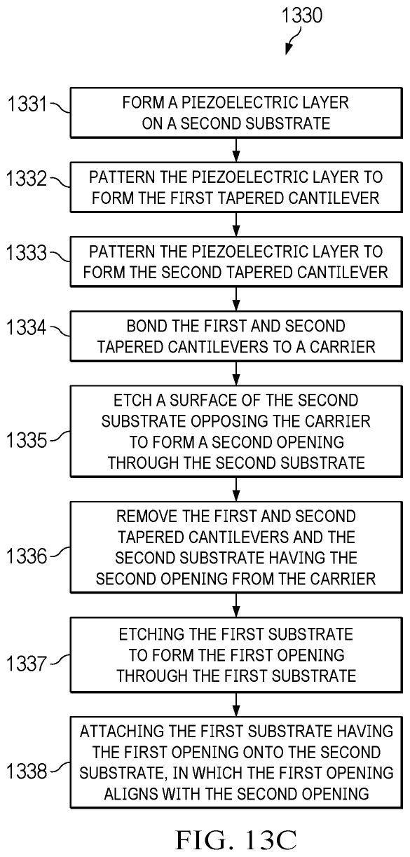

FIGS. 13A, 13B, and 13C illustrate methods 1300, 1320, and 1330, respectively, of forming a microphone with tapered cantilevers anchored to a post, according to some examples. Methods 1300, 1320, and 1330 summarize fabrication process shown by schematics of FIGS. 12A, 12B, 12C, 12D, 12E, 12F, 12G, and 12H. While blocks of methods 1300, 1320, and 1330 are shown in a particular order, the order can be modified. For example, some blocks may be performed before others and some blocks may be performed in parallel. In at least one example, methods 1300, 1320, and 1330 can be performed by software, hardware (e.g., fabrication tools), or a combination of them.

In at least one example, method 1300 comprises forming substrate 1202 at block 1301 by fabricating it for use as the substrate for tapered cantilevers, where substrate 1202 has opening 551. Substrate 1202 is later etched to form post portion 402a and peripheral portion 402b. At block 1302, first tapered cantilever 203a is formed having first edge 312 and second edge 311a, wherein first edge 312 is opposite to second edge 311a. First edge 312 is on substrate 1202, and at least part of second edge 311a is suspended over opening 551. Second edge 311a is longer than first edge 312. At block 1303, a second tapered cantilever 503 is formed having third edge 512 and fourth edge 511, wherein third edge 511 is opposite to fourth edge 511, wherein third edge 512 is on substrate 1202. In at least one example, at least part of fourth edge 511 is suspended over opening 551, fourth edge 511 being longer than third edge 512.

In at least one example, method 1320 describes the process of forming the cantilevers on a substrate. At block 1321, first tapered cantilever 203a and second tapered cantilever 503 are formed by forming a piezoelectric layer on a first surface of substrate 1202. At block 1322, the piezoelectric layer is patterned to form first tapered cantilever 203a. At block 1323, the piezoelectric layer is patterned to form second tapered cantilever 503. In at least one example, at block 1324, substrate 1202 is etched to form post portion 402a and peripheral portion 402b from a second surface opposing the first surface to form opening 551.

In at least one example, method 1330 describes the process of forming the cantilevers on a substrate. At block 1331, a piezoelectric layer is formed on a second substrate (e.g., handle wafer 1251). At block 1332, the piezoelectric layer is patterned to form the first tapered cantilever. At block 1333, the piezoelectric layer is patterned to form the second tapered cantilever. At block 1334, the first and second tapered cantilevers are bonded to carrier 1207. At block 1335, a surface of the second substrate opposing carrier 1207 is etched to form a second opening through the second substrate. At block 1336, the method further comprises removing the first and second tapered cantilevers and the second substrate having the second opening from carrier 1207. At block 1337, the first substrate is etched to form the first opening through the first substrate. At block 1338, the first substrate having the first opening is attached onto the second substrate, in which the first opening aligns with the second opening as illustrated by schematic 1280 of FIG. 12H.

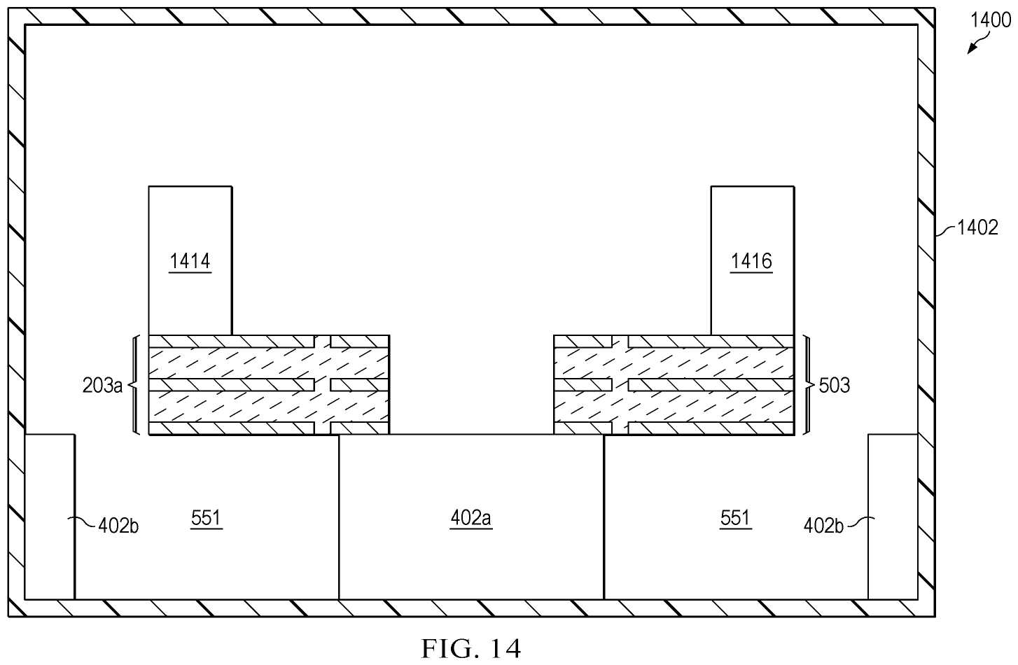

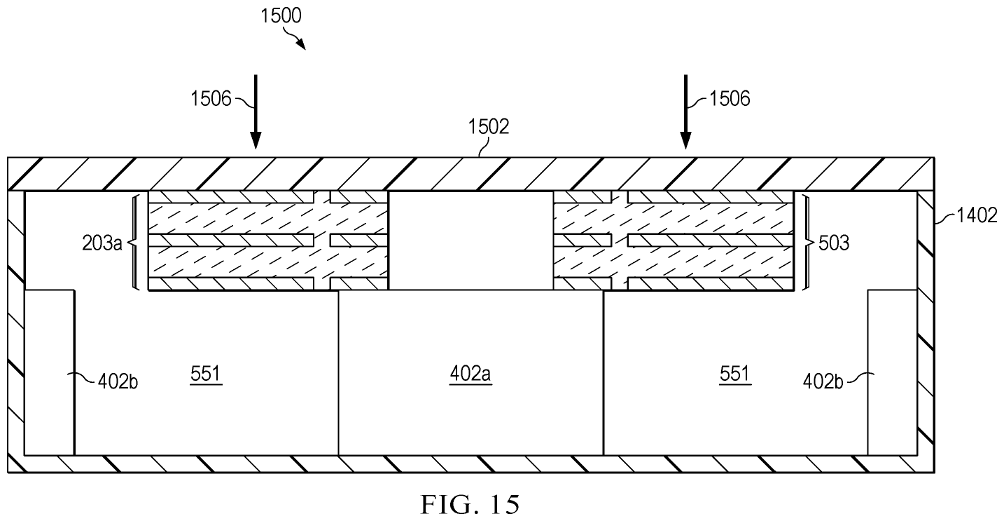

FIG. 14 and FIG. 15 are schematics illustrating example systems including a transducer device with tapered cantilevers, in accordance with some examples. FIG. 14 illustrates an example of an accelerometer 1400 including tapered cantilevers, such as tapered cantilevers 203a and 503 anchored on post portion 402a and suspended over openings 551. The tapered cantilevers can be enclosed in an enclosure 1402. Accelerometer 1400 also includes springs 1404 and 1406 and masses 1414 and 1416. Mass 1414 is coupled to cantilever 203a. Mass 1416 is coupled to cantilever 503. In at least one example, mass 1414 can include a metal layer deposited on cantilevers 203a, and mass 1416 can include a metal layer deposited on cantilever 503. As accelerometer 1400 moves, masses 1414 and 1416 can exert forces on cantilevers 203a and 503. The stresses in tapered cantilevers 203a and 503 can be amplified due to the tapered shapes of the cantilevers, and the amplified stress can be converted into voltages that can represent the acceleration (or speed of movement) of accelerometer 1400.

FIG. 15 illustrates an example of a stress sensor 1500 including tapered cantilevers, such as tapered cantilevers 203a and 503 anchored on post portion 402a and suspended over openings 551. The tapered cantilevers can be enclosed in an enclosure 1402, and a membrane 1502. Membrane 1502 can be mechanically coupled to (or directly attached on) tapered cantilevers 203a and 503. Membrane 1502 can transfer a force 1506 onto cantilever 203a and transfer a force 1508 onto cantilever 503. The stresses in tapered cantilevers 203a and 503 can be amplified due to the tapered shapes of the cantilevers, and the amplified stress can be converted into voltages that can represent the magnitudes of forces 1506 and 1508.

Following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is a transducer device comprising: a substrate having an opening through the substrate; a first tapered cantilever having a first edge and a second edge, wherein the first edge is opposite to the second edge, wherein the first edge is on the substrate, wherein at least part of the second edge is suspended over the opening, the second edge being longer than the first edge; and a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

Example 2 is a transducer device according to any example herein, particularly example 1, wherein the substrate includes a post portion, a peripheral portion, and an extension portion, the peripheral portion on a peripheral of the post portion and connected to the post portion via the extension portion, and the post portion and the extension portion abutting the opening, and wherein the first edge and the second edge are on the post portion.

Example 3 is a transducer device according to any example herein, particularly example 1, wherein the first tapered cantilever is adjacent to the extension portion.

Example 4 is a transducer device according to any example herein, particularly example 3, wherein the first tapered cantilever includes first electrodes, wherein the second tapered cantilever includes second electrodes, and wherein the transducer device includes metal interconnects on the extension portion, wherein the metal interconnects electrically coupled between the first and second electrodes and metal pads on the peripheral portion.

Example 5 is a transducer device according to any example herein, particularly example 1, wherein the substrate includes a post portion, a peripheral portion, and an extension portion, the peripheral portion on a peripheral of the post portion and connected to the post portion via the extension portion, wherein the first edge and the second edge are on the post portion, and wherein the first tapered cantilever is on the extension portion.

Example 6 is a transducer device according to any example herein, particularly example 5, wherein the opening is a first opening, and the substrate includes a second opening through the substrate, the extension portion separating between the first opening and the second opening.

Example 7 is a transducer device according to any example herein, particularly example 5, wherein the first tapered cantilever includes first electrodes, wherein the second tapered cantilever includes second electrodes, and wherein the transducer device includes bond wires that extend over the first or second tapered cantilevers and electrically coupled between the first and second electrodes and metal pads on the peripheral portion.

Example 8 is a transducer device according to any example herein, particularly example 1, wherein the first tapered cantilever is adjacent to the second tapered cantilever, and wherein the first and second tapered cantilevers are separated by a gap.

Example 9 is a transducer device according to any example herein, particularly example 1, wherein each of the second edge and the fourth edge includes a respective straight edge.

Example 10 is a transducer device according to any example herein, particularly example 1, wherein each of the second edge and the fourth edge includes a respective curved edge.

Example 11 is a transducer device according to any example herein, particularly example 1, wherein the first tapered cantilever includes a first piezoelectric bimorph cantilever, and wherein the second tapered cantilever includes a second piezoelectric bimorph cantilever.

Example 12 is a transducer device according to any example herein, particularly example 2, further including a protrusion structure on the peripheral portion across the second edge and the fourth edge.

Example 13 is a transducer device according to any example herein, particularly example 1, wherein the first tapered cantilever includes first electrodes, wherein the second tapered cantilever includes second electrodes, and wherein the transducer device further includes a voltage source electrically coupled to the first and second electrodes.

Example 14 is a transducer device according to any example herein, particularly example 1, wherein the first tapered cantilever and the second tapered cantilever are configured as a sensor or a transducer.

Example 15 is a system comprising: a case; an integrated circuit; and a transducer device coupled to the integrated circuit, wherein the integrated circuit and the transducer device are covered by the case, wherein the transducer device includes: a substrate having an opening through the substrate; a first tapered cantilever having a first edge and a second edge, wherein the first edge is opposite to the second edge, wherein the first edge is on the substrate, wherein at least part of the second edge is suspended over the opening, the second edge being longer than the first edge, and the first tapered cantilever including first electrodes electrically coupled to the integrated circuit; and a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge, and the second tapered cantilever including second electrodes electrically coupled to the integrated circuit.

Example 16 is a system according to any example herein, particularly example 15, wherein the substrate includes a post portion, a peripheral portion, and an extension portion, the peripheral portion on a peripheral of the post portion and connected to the post portion via the extension portion, and the post portion and the extension portion abutting the opening, and wherein the first edge and the second edge are on the post portion.

Example 17 is a system according to any example herein, particularly example 16, wherein the first tapered cantilever is adjacent to the extension portion.

Example 18 is a system according to any example herein, particularly example 17, wherein the first tapered cantilever includes first electrodes, wherein the second tapered cantilever includes second electrodes, and wherein the transducer device includes metal interconnects on the extension portion, wherein the metal interconnects electrically coupled between the first and second electrodes and metal pads on the peripheral portion.

Example 19 is a system according to any example herein, particularly example 18, wherein the first tapered cantilever is on the extension portion.

Example 20 is a system according to any example herein, particularly example 15, wherein the integrated circuit includes a receive circuit configured to receive first signals via the first and second electrodes and generate audio signals based on the first signals.

Example 21 is a system according to any example herein, particularly example 15, wherein the integrated circuit includes a transmit circuit configured to transmit DC signals via the first and second electrodes to set a first gap between the second edge and the substrate and a second gap between the fourth edge and the substrate.

Example 21a a system according to any example herein, particularly example 15, wherein the integrated circuit is configured to operate the transducer device as at least one of: a microphone, a speaker, a stress sensor, an accelerometer, or an energy harvester device.

Example 22 is a method comprising: forming a substrate having an opening through the substrate; forming a first tapered cantilever having a first edge and a second edge, wherein the first edge is opposite to the second edge, wherein the first edge is on the substrate, wherein at least part of the second edge is suspended over the opening, the second edge being longer than the first edge; and forming a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

Example 23 is a method according to any example herein, particularly example 22, further comprising: forming a piezoelectric layer on a first surface of the substrate; patterning the piezoelectric layer to form the first tapered cantilever; patterning the piezoelectric layer to form the second tapered cantilever; and etching the substrate from a second surface opposing the first surface to form the opening.

Example 24 is a method according to any example herein, particularly example 23, wherein the substrate is a first substrate, the opening is a first opening, and the method further comprises: forming a piezoelectric layer on a second substrate; patterning the piezoelectric layer to form the first tapered cantilever; patterning the piezoelectric layer to form the second tapered cantilever; bonding the first and second tapered cantilevers to a carrier; etching a surface of the second substrate opposing the carrier to form a second opening through the second substrate; removing the first and second tapered cantilevers and the second substrate having the second opening from the carrier; etching the first substrate to form the first opening through the first substrate; and attaching the first substrate having the first opening onto the second substrate, in which the first opening aligns with the second opening.

Example 25 is a transducer device comprising: a structure; a first tapered cantilever having a first edge attached to the structure and a second edge away from the first edge, wherein the second edge is longer than the first edge; and a second tapered cantilever having a third edge attached to the structure and a fourth edge away from the third edge, wherein the third edge is longer than the second edge.

Example 26 is a transducer device according to any example herein, particularly example 25, wherein the structure is configured as a post to anchor a plurality of tapered cantilevers including the first tapered cantilever and the second tapered cantilever.

Example 27 is a transducer device according to any example herein, particularly example 25, wherein the first tapered cantilever and the second tapered cantilever are separated by a gap.

Example 28 is a transducer device according to any example herein, particularly example 25, wherein the second edge and the third edge have straight edges.

Example 29 is a transducer device according to any example herein, particularly example 25, wherein the second edge and the third edge have curved edges.

Example 30 is a transducer device according to any example herein, particularly example 25, includes a metal pad coupled to the first edge and the third edge of the first tapered cantilever and the second tapered cantilever, respectively.

Example 31 is a transducer device according to any example herein, particularly example 25, includes a substrate adjacent to the first tapered cantilever and the second tapered cantilever.

Example 32 is a transducer device according to any example herein, particularly example 31, wherein the substrate includes at least one opening configured to allow fluid to interact with the second edge of the first tapered cantilever and the second tapered cantilever.

Example 33 is a transducer device according to any example herein, particularly example 25, wherein the second edge and the fourth edge hang over the substrate.

Example 34 is a transducer device according to any example herein, particularly example 25, wherein the first tapered cantilever is a first piezoelectric bimorph cantilever flap, and wherein the second tapered cantilever is a second piezoelectric bimorph cantilever flap.

Example 35 is a transducer device according to any example herein, particularly example 25, wherein the structure includes metal which is coupled to the first edge of the first tapered cantilever and the third edge of the second tapered cantilever.

Example 36 is a transducer device according to any example herein, particularly example 25, wherein the structure is a first structure, wherein the transducer device includes a second structure adjacent to the second edge of the first tapered cantilever and the fourth edge of the second tapered cantilever.

Example 37 is a transducer device according to any example herein, particularly example 36, wherein the second structure is configured as a dam around and adjacent to the second edge of the first tapered cantilever and the fourth edge of the second tapered cantilever.

Example 38 is a transducer device according to any example herein, particularly example 25, wherein the first tapered cantilever and the second tapered cantilever are configured as a sensor or a transducer.

Example 39 is a transducer device comprising: a post; and a plurality of tapered cantilevers having a first edge attached to the post and a second edge away from the first edge, wherein the plurality of tapered cantilevers is positioned around the post.

Example 40 is a transducer device according to any example herein, particularly example 39, wherein the plurality of tapered cantilevers includes a first tapered cantilever and a second tapered cantilever, and wherein the first tapered cantilever and the second tapered cantilever are separated by a gap.

Example 41 is a transducer device according to any example herein, particularly example 39, includes a gap between two tapered cantilevers of the plurality of tapered cantilevers, wherein the gap is configured to route a metal to the post, wherein the transducer device includes a metal pad coupled to the metal.

Example 42 is a system comprising: a case; an integrated circuit; and a transducer device coupled to the integrated circuit, wherein the integrated circuit and the transducer device are covered by the case, wherein the transducer device includes: a post; and a plurality of tapered cantilevers having a first edge attached to the post and a second edge away from the first edge, wherein the plurality of tapered cantilevers is positioned around the post.

Example 43 is a system according to any example herein, particularly example 42, wherein the plurality of tapered cantilevers includes a first tapered cantilever and a second tapered cantilever, wherein the first tapered cantilever and the second tapered cantilever are separated by a gap.

Example 44 is a system according to any example herein, particularly example 42, including a gap between two tapered cantilevers of the plurality of tapered cantilevers, wherein the gap is configured to route a metal to the post, wherein the transducer device includes a metal pad coupled to the metal.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

What is claimed is:

1. A transducer device comprising:
a substrate having an opening through the substrate;
a first tapered cantilever having a first edge and a second edge, wherein the first edge is opposite to the second edge, wherein the first edge is on the substrate, wherein at least part of the second edge is suspended over the opening, the second edge being longer than the first edge; and
a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

2. The transducer device of claim 1, wherein the substrate includes a post portion, a peripheral portion, and an extension portion, the peripheral portion on a peripheral of the post portion and connected to the post portion via the extension portion, and the post portion and the extension portion abutting the opening, and wherein the first edge and the second edge are on the post portion.

3. The transducer device of claim 2, wherein the first tapered cantilever is adjacent to the extension portion.

4. The transducer device of claim 3, wherein the first tapered cantilever includes first electrodes, wherein the second tapered cantilever includes second electrodes, and wherein the transducer device includes metal interconnects on the extension portion, wherein the metal interconnects electrically coupled between the first and second electrodes and metal pads on the peripheral portion.

5. The transducer device of claim 1, wherein the substrate includes a post portion, a peripheral portion, and an extension portion, the peripheral portion on a peripheral of the post portion and connected to the post portion via the extension portion, wherein the first edge and the second edge are on the post portion, and wherein the first tapered cantilever is on the extension portion.

6. The transducer device of claim 5, wherein the opening is a first opening, and the substrate includes a second opening through the substrate, the extension portion separating between the first opening and the second opening.

7. The transducer device of claim 5, wherein the first tapered cantilever includes first electrodes, wherein the second tapered cantilever includes second electrodes, and wherein the transducer device includes bond wires that extend over the first or second tapered cantilevers and electrically coupled between the first and second electrodes and metal pads on the peripheral portion.

8. The transducer device of claim 1, wherein the first tapered cantilever is adjacent to the second tapered cantilever, and wherein the first and second tapered cantilevers are separated by a gap.

9. The transducer device of claim 1, wherein each of the second edge and the fourth edge includes a respective straight edge.

10. The transducer device of claim 1, wherein each of the second edge and the fourth edge includes a respective curved edge.

11. The transducer device of claim 1, wherein the first tapered cantilever includes a first piezoelectric bimorph cantilever, and wherein the second tapered cantilever includes a second piezoelectric bimorph cantilever.

12. The transducer device of claim 2, further including a protrusion structure on the peripheral portion across the second edge and the fourth edge.

13. The transducer device of claim 1, wherein the first tapered cantilever includes first electrodes, wherein the second tapered cantilever includes second electrodes, and wherein the transducer device further includes a voltage source electrically coupled to the first and second electrodes.

14. The transducer device of claim 1, wherein the first tapered cantilever and the second tapered cantilever are configured as a sensor or a transducer.

15. A system comprising:
a case;
an integrated circuit; and
a transducer device coupled to the integrated circuit, wherein the integrated circuit and the transducer device are covered by the case, wherein the transducer device includes:
a substrate having an opening through the substrate;
a first tapered cantilever having a first edge and a second edge, wherein the first edge is opposite to the second edge, wherein the first edge is on the substrate, wherein at least part of the second edge is suspended over the opening, the second edge being longer than the first edge, and the first tapered cantilever including first electrodes electrically coupled to the integrated circuit; and
a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge, and the second tapered cantilever including second electrodes electrically coupled to the integrated circuit.

16. The system of claim 15, wherein the substrate includes a post portion, a peripheral portion, and an extension portion, the peripheral portion on a peripheral of the post portion and connected to the post portion via the extension portion, and the post portion and the extension portion abutting the opening, and wherein the first edge and the second edge are on the post portion.

17. The system of claim 16, wherein the first tapered cantilever is adjacent to the extension portion.

18. The system of claim 17, wherein the first tapered cantilever includes first electrodes, wherein the second tapered cantilever includes second electrodes, and wherein the transducer device includes metal interconnects on the extension portion, wherein the metal interconnects electrically coupled between the first and second electrodes and metal pads on the peripheral portion.

19. The system of claim 18, wherein the first tapered cantilever is on the extension portion.

20. The system of claim 15, wherein the integrated circuit includes a receive circuit configured to receive first signals via the first and second electrodes and generate audio signals based on the first signals.

21. The system of claim 15, wherein the integrated circuit includes a transmit circuit configured to transmit DC signals via the first and second electrodes to set a first gap between the second edge and the substrate and a second gap between the fourth edge and the substrate.

22. The system of claim 15, wherein the integrated circuit is configured to operate the transducer device as at least one of: a microphone, a speaker, a stress sensor, an accelerometer, or an energy harvester device.

23. A method comprising:
forming a substrate having an opening through the substrate;
forming a first tapered cantilever having a first edge and a second edge, wherein the first edge is opposite to the second edge, wherein the first edge is on the substrate, wherein at least part of the second edge is suspended over the opening, the second edge being longer than the first edge; and
forming a second tapered cantilever having a third edge and a fourth edge, wherein the third edge is opposite to the fourth edge, wherein the third edge is on the substrate, wherein at least part of the fourth edge is suspended over the opening, the fourth edge being longer than the third edge.

24. The method of claim 23, further comprising:
forming a piezoelectric layer on a first surface of the substrate;
patterning the piezoelectric layer to form the first tapered cantilever;
patterning the piezoelectric layer to form the second tapered cantilever; and
etching the substrate from a second surface opposing the first surface to form the opening.

25. The method of claim 23, wherein the substrate is a first substrate, the opening is a first opening, and the method further comprises:
forming a piezoelectric layer on a second substrate;
patterning the piezoelectric layer to form the first tapered cantilever;
patterning the piezoelectric layer to form the second tapered cantilever;
bonding the first and second tapered cantilevers to a carrier;
etching a surface of the second substrate opposing the carrier to form a second opening through the second substrate;
removing the first and second tapered cantilevers and the second substrate having the second opening from the carrier;
etching the first substrate to form the first opening through the first substrate; and
attaching the first substrate having the first opening onto the second substrate, in which the first opening aligns with the second opening.
